(19) United States
(12) Patent Application Publication
(10) Pub. No.: US 2026/0033094 A1
(43) Pub. Date: Jan. 29, 2026

(54) Display Device

(71) Applicant: LG Display Co., Ltd., Seoul (KR)

(72) Inventors: Jae Yong Yun, Paju-si (KR); Kyoung June Jung, Paju-si (KR); Jae Kwang Lee, Paju-si (KR); Hae Sung Lee, Paju-si (KR); Jeen Wook Kwon, Paju-si (KR)

(21) Appl. No.: 19/252,792

(22) Filed: Jun. 27, 2025

(30) Foreign Application Priority Data
Jul. 24, 2024 (KR) 10-2024-0097822

(51) Int. Cl. H10H 29/80; H10H 29/37

(52) U.S. Cl. CPC H10H 29/842; H10H 29/37

(57) ABSTRACT

A display device may include a substrate, a plurality of inorganic light-emitting elements disposed on the substrate, a first optical layer disposed around the plurality of inorganic light-emitting elements, a second optical layer disposed on the plurality of inorganic light-emitting elements and the first optical layer, and a first passivation layer disposed on the first optical layer such that the first passivation layer is farther from the substrate than the first optical layer.

### CROSS-REFERENCE TO RELATED APPLICATION

This application claims priority to and the benefit of Republic of Korea Patent Application No. 10-2024-0097822, filed on Jul. 24, 2024, which is hereby incorporated by reference in its entirety.

### BACKGROUND

### 1. Field of Technology

The present specification relates to a display device.

### 2. Discussion of Related Art

Display devices are being applied to various electronic devices such as a television (TV), a mobile phone, a notebook, a tablet, and the like.

Display devices include an organic light-emitting display (OLED) device which emits light by itself, a liquid crystal display (LCD) device which requires a separate light source, and the like.

Recently, display devices including light-emitting elements (light-emitting diodes, LEDs) are attracting attention as next generation display devices. The light-emitting elements are formed of an inorganic material rather than an organic material, and thus the display devices including light-emitting elements may have a faster lighting speed and higher luminous efficacy, and display higher brightness images compared to an LCD device or OLED device.

### SUMMARY

As moisture or the like penetrate from the outside into a display device including inorganic light-emitting elements (for example, micro light-emitting diodes (micro LEDs)), the reliability of the display device may decrease.

An embodiment of the present specification is directed to providing a display device whose reliability is enhanced.

The objects according to embodiments of the present specification are not limited to the above-described objects, and other objects that are not mentioned will be clearly understood by those skilled in the art from the following description.

In one embodiment, a display device comprises: a substrate; a plurality of inorganic light-emitting elements on the substrate; a first optical layer around the plurality of inorganic light-emitting elements; a second optical layer on the plurality of inorganic light-emitting elements and the first optical layer; and a first passivation layer on the first optical layer such that the first passivation layer is farther from the substrate than the first optical layer.

In one embodiment, a display device comprises: a display panel including a plurality of pixels, each of the plurality of pixels including a plurality of light-emitting elements; an optical layer in the plurality of pixels; and a trench in the plurality of pixels, wherein the trench includes a first trench between a first pair of light-emitting elements from the plurality of light-emitting elements and a second trench between a second pair of light-emitting elements from the plurality of light-emitting elements, and wherein the optical layer includes a first optical layer around the plurality of light-emitting elements and a second optical layer on the plurality of light-emitting elements and the first optical layer.

region and a non-display region that surrounds the display region; a first inorganic light-emitting element in the display region; a second inorganic light-emitting element in the non-display region; a first optical layer around the first inorganic light-emitting element in the display region and around the second inorganic light-emitting element in the non-display region; a second optical layer on the first inorganic light-emitting element and a first portion of the first optical layer in the display region and on the second inorganic light-emitting element and a second portion of the first optical layer in the non-display region; and a trench through the first optical layer and the second optical layer in the non-display region, wherein the trench is disposed between the first inorganic light-emitting element and the second inorganic light-emitting element.

Specific details according to the various examples of the present specification other than solutions to the above-mentioned problems are included in the description and drawings described below.

### BRIEF DESCRIPTION OF THE DRAWINGS

The following drawings attached to this specification illustrate preferred embodiments of the present invention and, together with the detailed description of the invention to be described below, serve to further understand the technical idea of the present invention, and therefore the present invention should not be construed as being limited to matters described in such drawings, in which:

FIG. 1 is an exploded perspective view of a display device according to an embodiment of the present specification;

FIG. 2 is a plan view showing the display device according to the embodiment of the present specification;

FIG. 3 is a plan view showing the display device according to the embodiment of the present specification;

FIG. 4 is a plan view showing the display device according to the embodiment of the present specification;

FIG. 5 is a plan view showing the display device according to the embodiment of the present specification;

FIG. 6 is a plan view showing the display device according to the embodiment of the present specification;

FIG. 7 is a plan view showing a display device according to an embodiment of the present specification;

FIG. 8 is a plan view showing a display device according to an embodiment of the present specification;

FIG. 9 is a plan view showing a display device according to an embodiment of the present specification;

FIG. 10 is a plan view showing a display device according to an embodiment of the present specification;

FIG. 11 is a plan view showing a display device according to an embodiment of the present specification;

FIG. 12 is a plan view showing a display device according to an embodiment of the present specification;

FIG. 13 is a plan view showing a display device according to an embodiment of the present specification;

FIG. 14 is a plan view showing a display device according to an embodiment of the present specification;

FIG. 15 is a plan view showing a display device according to an embodiment of the present specification;

FIG. 16 is a plan view showing a display device according to an embodiment of the present specification;

FIG. 17 is a plan view showing a display device according to an embodiment of the present specification;

FIG. 18 is an enlarged view showing the display device according to the embodiment of the present specification;

FIG. 19 is a view showing a circuit structure according to the embodiment of the present specification;

FIG. 20 is a cross-sectional view showing the display device according to the embodiment of the present specification;

FIG. 21 is a cross-sectional view showing the display device according to the embodiment of the present specification;

FIG. 22 is a cross-sectional view showing the display device according to the embodiment of the present specification;

FIG. 23 is a cross-sectional view showing the display device according to the embodiment of the present specification;

FIG. 24 is a cross-sectional view showing the display device according to the embodiment of the present specification;

FIG. 25 is a cross-sectional view showing the display device according to the embodiment of the present specification;

FIG. 26 is a cross-sectional view showing the display device according to the embodiment of the present specification;

FIG. 27 is a cross-sectional view showing the display device according to the embodiment of the present specification;

FIG. 28 is a cross-sectional view showing the display device according to the embodiment of the present specification;

FIG. 29 is a cross-sectional view showing the display device according to the embodiment of the present specification;

FIG. 30 is a cross-sectional view showing a display device according to an embodiment of the present specification;

FIG. 31 is a cross-sectional view showing a display device according to an embodiment of the present specification;

FIG. 32 is a cross-sectional view showing a display device according to an embodiment of the present specification;

FIG. 33 is a cross-sectional view showing a display device according to an embodiment of the present specification;

FIG. 34 is a cross-sectional view showing a display device according to an embodiment of the present specification;

FIG. 35 is a cross-sectional view showing a display device according to an embodiment of the present specification;

FIG. 36 is a cross-sectional view showing the display device according to the embodiment of the present specification;

FIG. 37 is a cross-sectional view showing a display device according to an embodiment of the present specification;

FIG. 38 is a cross-sectional view showing a display device according to an embodiment of the present specification;

FIG. 39 is a cross-sectional view showing a display device according to an embodiment of the present specification;

FIG. 40 is a view showing a device to which the display devices according to the embodiments of the present specification are applied;

FIG. 41 is a view showing a device to which the display devices according to the embodiments of the present specification are applied;

FIG. 42 is a view showing a device to which the display devices according to the embodiments of the present specification are applied; and

FIG. 43 is a view showing a device to which the display devices according to the embodiments of the present specification are applied.

### DETAILED DESCRIPTION

Advantages and features of the present specification and methods of achieving them will become apparent with reference to the following embodiments, which are described in detail, in conjunction with the accompanying drawings. However, the present specification is not limited to the embodiments to be described below and may be implemented in various different forms, the embodiments are only provided to completely disclose the present specification and completely convey the scope of the present specification to those skilled in the art.

Since the shapes, sizes, proportions, angles, numbers, and the like disclosed in the drawings for describing the embodiments of the present specification are only exemplary, the present specification is not limited to the items shown in the drawings. The same reference number indicates the same components throughout the specification. Further, in describing the present specification, when it is determined that a detailed description of related known technology may unnecessarily obscure the gist of the present specification, the detailed description thereof will be omitted. When “providing,” “including,” “having,” “consisting of,” and the like are used herein, other parts may be added unless ‘only’ is used. A case in which a component is expressed in a singular form may include a plural form unless explicitly stated otherwise.

In interpreting a component, the component is interpreted as including a margin of error even when there is no separate explicit description of the margin of error.

In a description of a positional relationship, when the positional relationship of two parts such as “on,” “at an upper portion,” “at a lower portion,” “next to,” “adjacent to,” or the like is described, one or more other parts may be located between two components unless “immediately,” “directly,” “close to” is used.

In a description of a temporal relationship, when the temporal relationship is described as “after,” “following,” “and then,” “before,” or the like, non-consecutive cases may also be included unless “immediately” or “directly” is used.

Although first, second, and the like are used to describe various components, these components are not limited by these terms. These terms are only used to distinguish one component from another component. Accordingly, a first component described below may also be a second component within the technical spirit of the present specification.

Terms, such as first, second, A, B, (a), and (b) may be used to describe components of the present specification. These terms are only for the purpose of distinguishing one component from another component, and the nature, sequence, order, or the like of the corresponding components is not limited by these terms.

When a component is described as being “connected,” “coupled,” “linked,” or “attached” to another component, it should be understood that the component may be directly connected, coupled, linked, or attached to the other component, but another component may be interposed between the components which may be indirectly connected, coupled, linked, or attached to each other unless explicitly stated otherwise.

When a component or layer is described as “being in contact with” or “overlapping” another component or layer, it should be understood that the component or layer may be in direct contact with or directly overlap another component or layer, but another component may be interposed between the components which may be in direct contact with or directly overlap each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which relationships therebetween are perpendicular to each other, but mean that a configuration of the present specification has a broader directionality within a range in which it may functionally act.

Features of various embodiments of the present specification may be partially or entirely combined with each other, and technically, various interconnections and operations are possible, and the embodiments may be implemented independently of each other or together in a related relationship.

Hereinafter, various embodiments of the present specification will be described in detail with reference to the accompanying drawings.

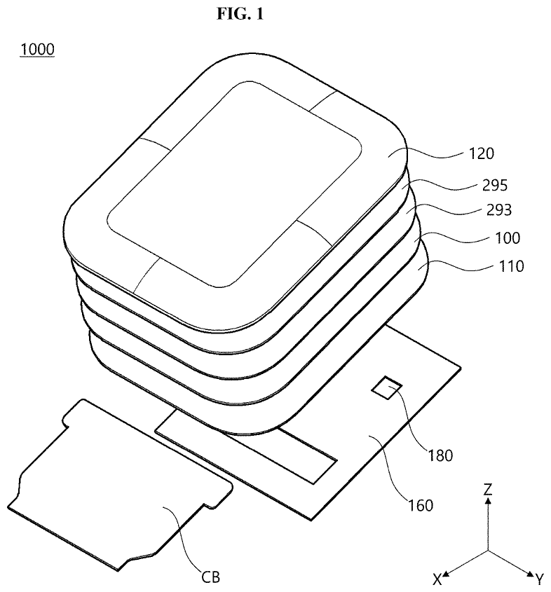

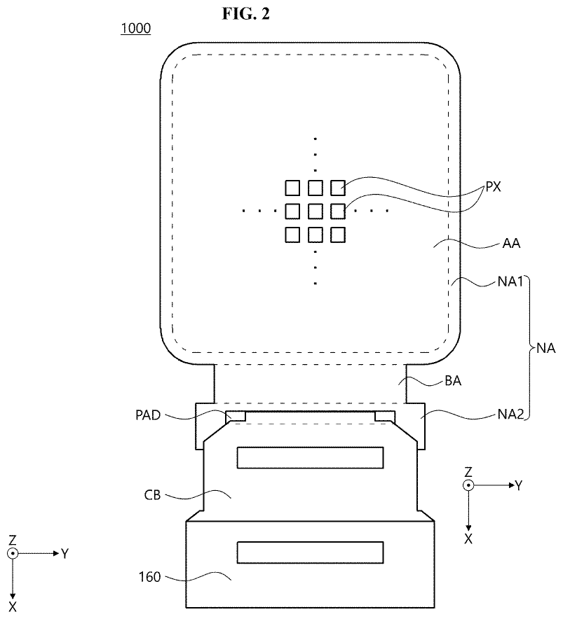

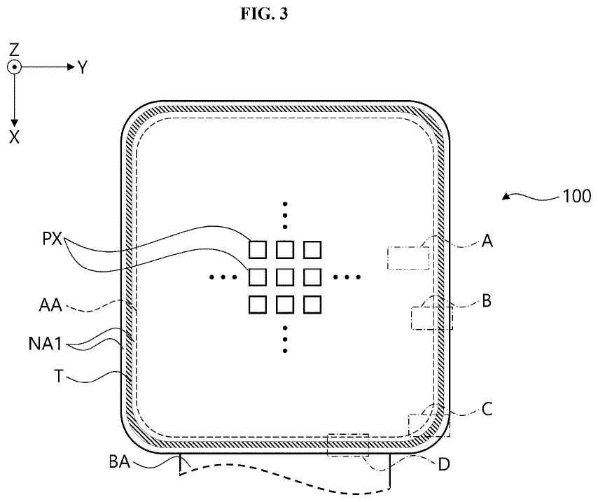

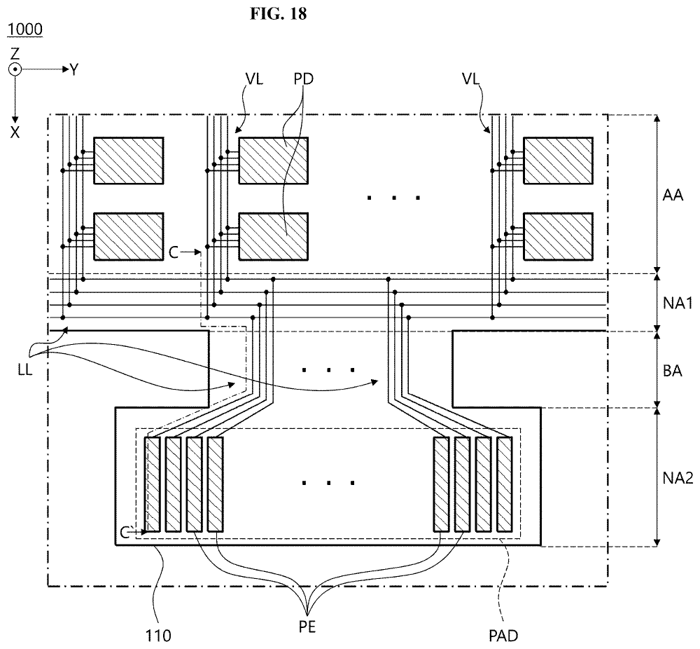

FIG. 1 is an exploded perspective view of a display device according to an embodiment of the present specification. FIG. 2 is a plan view showing the display device according to the embodiment of the present specification. FIG. 3 is a plan view showing the display device according to the embodiment of the present specification. FIG. 18 is an enlarged view showing the display device according to the embodiment of the present specification.

Referring to FIGS. 1, 2, and 18, a display device 1000 according to the embodiment of the present specification may include a display panel 100, a polarization layer 293, a second adhesive layer 295, a cover member 120, a substrate 110, a flexible circuit board CB, and a printed circuit board 160.

For example, the display device 1000 may include the substrate 110. The substrate 110 may be a member which supports other components of the display device 1000. The substrate 110 may be formed of an insulating material. For example, the substrate 110 may be formed of glass, a resin, or the like. Further, the substrate 110 may be formed of a material having flexibility. For example, the substrate 110 may be formed of a plastic material having flexibility such as polyimide (PI) or the like. However, the embodiments of the present specification are not limited thereto.

The display panel 100 may implement information, a video, and/or an image provided to a user. For example, the display panel 100 may include a display region AA and a non-display region NA. For example, the substrate 110 may include the display region AA and the non-display region NA. The display region AA and the non-display region NA are not limited to the substrate 110 but may be provided throughout the display device 1000.

The display region AA may be a region where an image is displayed. The display region AA may include a plurality of pixels PX. Each of the plurality of pixels PX may be composed of a plurality of subpixels. A plurality of light-emitting elements may be disposed in each of the plurality of subpixels. The plurality of light-emitting elements may be configured differently depending on the type of display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present specification are not limited thereto.

The non-display region NA may be a region where an image is not displayed. Various lines and circuits for driving the plurality of pixels PX of the display region AA may be disposed in the non-display region NA. For example, in the non-display region NA, various lines and driving circuits may be mounted, and a pad portion PAD to which an integrated circuit, a printed circuit, and the like are connected may be disposed, but the embodiments of the present specification are not limited thereto.

For example, the driving circuit may be a data driving circuit and/or a gate driving circuit, but the embodiments of the present specification are not limited thereto. Lines through which control signals for controlling the driving circuits are supplied may be disposed on the display panel 100. For example, the control signals may include various timing signals including a clock signal, an input data enable signal, and a synchronization signal, but the embodiments of the present specification are not limited thereto. The control signals may be received through the pad portion PAD. For example, link lines LL for transmitting signals may be disposed in the non-display region NA. For example, driving components such as the flexible circuit board CB and the printed circuit board 160 may be connected to the pad portion PAD.

According to the present specification, the non-display region NA may include a first non-display region NA1, a bending region BA, and a second non-display region NA2. For example, the first non-display region NA1 may be a region surrounding at least a portion of the display region AA. The bending region BA may be a region extending from at least one side of a plurality of sides of the first non-display region NA1 and may be a bendable region. The second non-display region NA2 may be a region extending from the bending region BA, and the pad portion PAD may be disposed in the second non-display region NA2. For example, the bending region BA may be in a bent state, and the remaining region of the substrate 110 excluding the bending region BA may be in a flat state. In this case, as the bending region BA is bent, the second non-display region NA2 may be located on a rear surface of the display region AA. However, the embodiments of the present specification are not limited thereto.

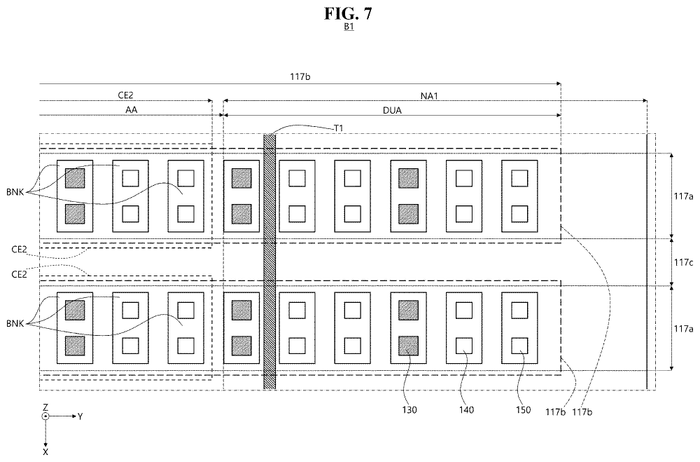

A trench T in FIG. 3 is described below with reference to FIGS. 7 to 17.

The display region AA of the substrate 110 or the display device 1000 may be configured in various shapes depending on the design of the display device 1000. For example, the display region AA may be configured in a rectangular shape whose four corners are formed in a round shape, but the embodiments of the present specification are not limited thereto. For another example, the display region AA may be configured in a rectangular shape whose four corners are formed in a right-angled shape, a circular shape, or the like, but the embodiments of the present specification are not limited thereto.

According to the present specification, a width of the second non-display region NA2 where a plurality of pad electrodes PE are disposed may be wider than a width of the bending region BA where only a plurality of link lines LL are disposed. Further, a width of the display region AA where the plurality of subpixels are disposed may be wider than the width of the bending region BA where only the plurality of link lines LL are disposed. The drawings show that the width of the bending region BA is narrower than widths of other regions of the substrate 110, but the shape of the substrate 110 including the bending region BA is exemplary, and the embodiments of the present specification are not limited thereto.

Referring to FIG. 18, a plurality of pixel driving circuits PD may be disposed in the display region AA. The plurality of pixel driving circuits PD may be circuits for driving the light-emitting elements of the plurality of subpixels. Each of the plurality of pixel driving circuits PD includes a plurality of transistors including a driving transistor, a storage capacitor, and the like and may control the light-emitting operations of the plurality of light-emitting elements by supplying control signals, power, and a driving current to the light-emitting elements of the plurality of subpixels. For example, the pixel driving circuit PD may include a power line and a signal line for controlling the emission on/off and/or emission time of the light-emitting elements. For example, the plurality of pixel driving circuits PD may be driving drivers manufactured using a metal-oxide-silicon field effect transistor (MOSFET) manufacturing process on a semiconductor substrate, but the embodiments of the present specification are not limited thereto. The driving driver may include the plurality of pixel driving circuits PD and may drive the plurality of subpixels.

Referring to FIG. 1 together, the flexible circuit board CB and the printed circuit board 160 may be disposed under the display panel 100. The flexible circuit board CB and the printed circuit board 160 may be disposed at least on an edge of one side of the display panel 100, but the embodiments of the present specification are not limited thereto. One side of the flexible circuit board CB may be attached to the display panel 100 and the other side may be attached to the printed circuit board 160, but the embodiments of the present specification are not limited thereto. The flexible circuit board CB may be a flexible film, but the embodiments of the present specification are not limited thereto.

The pad portion PAD including a plurality of pad electrodes PE may be disposed in the second non-display region NA2. Driving components including one or more flexible circuit boards (or flexible films) CB and the printed circuit board 160 may be attached or bonded to the pad portion PAD. The plurality of pad electrodes PE of the pad portion PAD are electrically connected to one or more flexible circuit boards (or flexible films) CB, and various signals (or power) from the printed circuit board 160 and the flexible circuit boards (or flexible films) CB may be transmitted to the plurality of pixel driving circuits PD of the display region AA

The flexible circuit board (or flexible film) CB may be a film in which various components are disposed on a flexible base film. For example, a driving integrated circuit (IC) such as a gate driver IC or a data driver IC may be disposed on the flexible circuit board (or flexible film) CB, but the embodiments of the present specification are not limited thereto. The driving IC may be a component which processes data and a driving signal for displaying an image. The driving IC may be disposed in a manner such as a chip on glass (COG), a chip on film (COF), a tape carrier package (TCP), or the like depending on a mounting method, but the embodiments of the present specification are not limited thereto. The flexible circuit board (or flexible film) CB may be attached or bonded to the plurality of pad electrodes PE through a conductive adhesive layer, but the embodiments of the present specification are not limited thereto.

The printed circuit board 160 may be a component which is electrically connected to one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various components for supplying various signals to the driving IC may be disposed on the printed circuit board 160. For example, various components such as a timing controller, a power supply, a memory, a processor, and the like may be disposed on the printed circuit board 160. For example, the printed circuit board 160 may include a power management integrated circuit (PMIC), but the embodiments of the present specification are not limited thereto.

The printed circuit board 160 may include at least one hole 180, but the embodiments of the present specification are not limited thereto. An internal component which detects ambient light, temperature, or the like which may be provided to a plurality of sensors may be disposed in a region corresponding to at least one hole 180. For example, the internal component may include an ambient light sensor (ALS) or a temperature sensor, but the embodiments of the present specification are not limited thereto. For example, the hole 180 may be a through hole or the like, but the embodiments of the present specification are not limited thereto.

Referring to FIG. 1, the polarization layer 293 may be disposed on the display panel 100. The polarization layer 293 may prevent or reduce the light generated from an external light source from entering the display panel 100 and affecting the light-emitting element or the like.

The cover member 120 may be disposed on the polarization layer 293. The cover member 120 may be a member for protecting the display panel 100. The second adhesive layer 295 may be disposed between the polarization layer 293 and the cover member 120. The cover member 120 may be attached to the display panel 100 by the second adhesive layer 295. The second adhesive layer 295 may include an optically clear adhesive (OCA), an optically clear resin (OCR), a pressure sensitive adhesive (PSA), or the like, but the embodiments of the present specification are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present specification are not limited thereto.

Referring to FIGS. 1, 2, and 18, the plurality of link lines LL may be disposed in the non-display region NA. The plurality of link lines LL may be lines which transmit various signals from one or more flexible circuit boards (or flexible films) CB and the printed circuit board 160 to the display region AA. The plurality of link lines LL may extend from the plurality of pad electrodes PE of the second non-display region NA2 toward the bending region BA and the first non-display region NA1 and may be electrically connected to a plurality of driving lines VL of the display region AA. The plurality of pixel driving circuits PD may be driven by receiving signals from one or more flexible circuit boards (or flexible films) CB and the printed circuit board 160 through the driving lines VL of the display region AA and the link lines LL of the non-display region NA.

For example, the plurality of driving lines VL may be lines for transmitting the signals output from the flexible circuit boards (or flexible films) CB and the printed circuit board 160 to the plurality of pixel driving circuits PD along with the plurality of link lines LL. The plurality of driving lines VL may be disposed in the display region AA and may be electrically connected to the plurality of pixel driving circuits PD. The plurality of driving lines VL may extend from the display region AA toward the non-display region NA and may be electrically connected to the plurality of link lines LL. Accordingly, the signals output from the flexible circuit boards (or flexible films) CB and the printed circuit board 160 may be respectively transmitted to the plurality of pixel driving circuits PD through the plurality of link lines LL and the plurality of driving lines VL.

As the bending region BA is bent, portions of the plurality of link lines LL may also be bent along with the bending region BA. Stress may be concentrated on portions of the bent link lines LL, and accordingly, cracks may occur in the link lines LL. Accordingly, the plurality of link lines LL may be formed of a conductive material having excellent flexibility to reduce cracks when the bending region BA is bent. For example, the plurality of link lines LL may be formed of a conductive material having excellent flexibility such as gold (Au), silver (Ag), aluminum (Al), or the like, but the embodiments of the present specification are not limited thereto. Further, the plurality of link lines LL may be formed of one of various conductive materials used in the display region AA. For example, the plurality of link lines LL may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present specification are not limited thereto. The plurality of link lines LL may be formed in a multi-layer structure including various conductive materials. For example, the plurality of link lines LL may be configured in a triple-layer structure of titanium (Ti)/aluminum (Al)/titanium (Ti), but the embodiments of the present specification are not limited thereto.

The plurality of link lines LL may be configured in various shapes to reduce stress. At least portions of the plurality of link lines LL disposed in the bending region BA may extend in the same direction as an extending direction of the bending region BA or may extend in a different direction from the extending direction of the bending region BA to reduce stress. For example, when the bending region BA extends in one direction from the first non-display region NA1 toward the second non-display region NA2, at least portions of the link lines LL disposed in the bending region BA may extend in a direction oblique to the one direction. For another example, at least portions of the plurality of link lines LL may be configured in various pattern shapes. For example, at least portions of the plurality of link lines LL disposed in the bending region BA may have a shape in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly disposed, but the embodiments of the present specification are not limited thereto. Accordingly, in order to minimize the stress concentrated on the plurality of link lines LL and cracks resulting from the stress, the plurality of link lines LL may be formed in various shapes including the above-described shapes, but the embodiments of the present specification are not limited thereto.

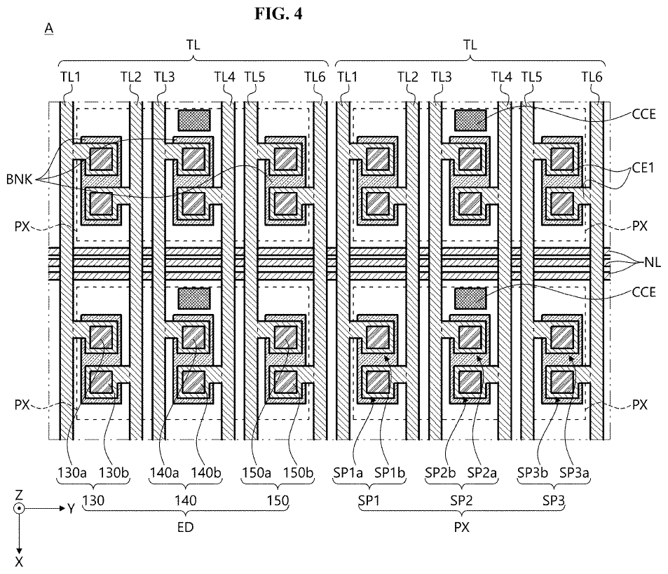

FIGS. 4 to 6 are plan views showing the display device according to the embodiment of the present specification.

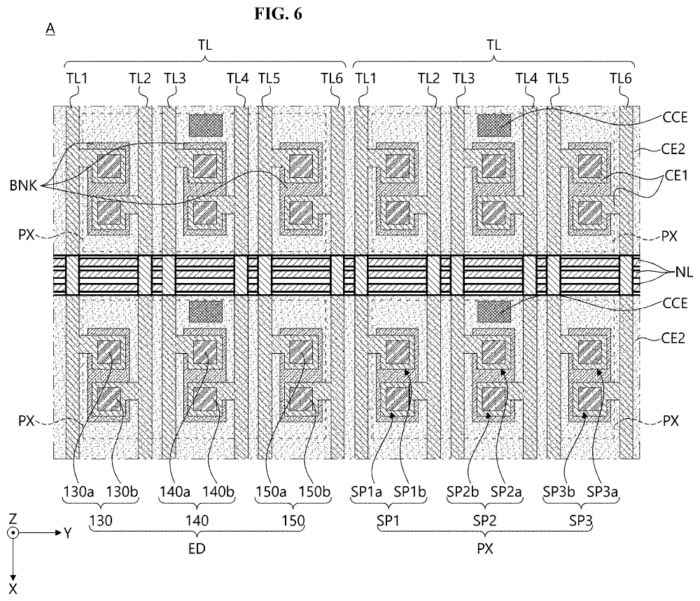

FIGS. 4 and 6 are enlarged views of the display region including the plurality of pixels. FIGS. 4 and 6 are partially enlarged views of portion A in FIG. 3.

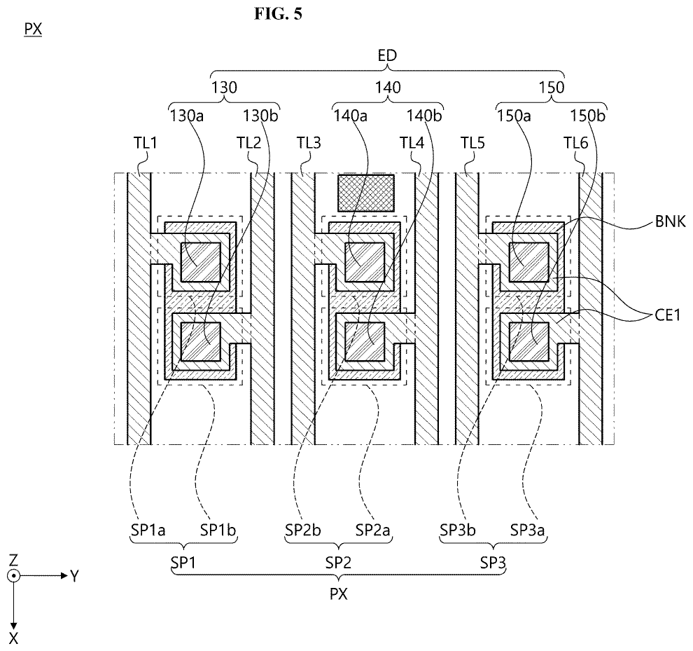

FIG. 5 is an enlarged view of the display region including one pixel. FIG. 5 is a partially enlarged view of one pixel PX.

In FIGS. 4 and 5, only a plurality of signal lines TL, a plurality of communication lines NL, a plurality of first electrodes CE1, a plurality of banks BNK, and a plurality of light-emitting elements ED are shown, but the embodiments of the present specification are not limited thereto. FIG. 6 is an enlarged plan view in which a plurality of second electrodes CE2 are additionally disposed in FIG. 4.

Referring to FIGS. 4 and 5, the plurality of pixels PX composed of a plurality of subpixels may be disposed in the display region AA. Each of the plurality of subpixels includes a light-emitting element ED and may independently emit light. The plurality of subpixels may be disposed in a matrix form, forming a plurality of rows and a plurality of columns, but the embodiments of the present specification are not limited thereto.

The plurality of subpixels may include a first subpixel SP1, a second subpixel SP2, and a third subpixel SP3. For example, one of the first subpixel SP1, the second subpixel SP2, and the third subpixel SP3 may be a red subpixel, another may be a green subpixel, and the remaining one may be a blue subpixel. The types of the plurality of subpixels are exemplary, and the embodiments of the present specification are not limited thereto.

Each of the plurality of pixels PX may include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may be composed of a 1-1 subpixel SP1a and a 1-2 subpixel SP1b. The pair of second subpixels SP2 may be composed of a 2-1 subpixel SP2a and a 2-2 subpixel SP2b. The pair of third subpixels SP3 may be composed of a 3-1 subpixel SP3a and a 3-2 subpixel SP3b. For example, one pixel PX may include the 1-1 subpixel SP1a and the 1-2 subpixel SP1b, the 2-1 subpixel SP2a and the 2-2 subpixel SP2b, and the 3-1 subpixel SP3a and the 3-2 subpixel SP3b, but the embodiments of the present specification are not limited thereto.

The plurality of subpixels forming one pixel PX may be arranged in various ways. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number and arrangement of the plurality of subpixels forming one pixel PX are exemplary, and the embodiments of the present specification are not limited thereto.

The plurality of signal lines TL may be disposed in regions between the plurality of subpixels. The plurality of signal lines TL may extend between the plurality of subpixels in a column direction. The plurality of signal lines TL may be lines which transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels. The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 of the light-emitting element ED. Accordingly, the anode voltage from the signal line TL may be transmitted to the anode electrode 134 of the light-emitting element ED through the first electrode CE1.

Accordingly, instead of forming a plurality of transistors and a plurality of storage capacitors in each of the plurality of subpixels, a structure of the display device 1000 may be simplified using a pixel driving circuit PD in which a plurality of pixel circuits are integrated. Further, as the circuits disposed in each of the plurality of subpixels are integrated into one pixel driving circuit PD, high efficiency and low power driving may be possible. The fact that the circuits disposed in each of the plurality of subpixels SP are integrated into one pixel driving circuit PD means that the plurality of pixel circuits capable of driving the plurality of light-emitting elements ED are included in the pixel driving circuit PD. The plurality of light-emitting elements ED may be driven by one pixel driving circuit PD in which the plurality of pixel circuits are integrated. For example, a 1-1 light-emitting element 130a, a 2-1 light-emitting element 140a, and a 3-1 light-emitting element 150a may be driven by one pixel driving circuit PD in which the plurality of pixel circuits are integrated. For example, although the light-emitting element ED may be formed in a vertical type structure, but the embodiments of the present specification are not limited thereto.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first subpixels SP1, respectively. The third signal line TL3 and the fourth signal line TL4 may be electrically connected to the pair of second subpixels SP2, respectively. The fifth signal line TL5 and the sixth signal line TL6 may be electrically connected to the pair of third subpixels SP3, respectively.

The first signal line TL1 may be disposed on one side of the pair of first subpixels SP1, and the second signal line TL2 may be disposed on another side of the pair of first subpixels SP1. The first signal line TL1 may be electrically connected to the first electrode CE1 of one of the pair of first subpixels SP1, for example, the 1-1 subpixel SP1a. The second signal line TL2 may be electrically connected to the first electrode CE1 of the other of the pair of first subpixels SP1, for example, the 1-2 subpixel SP1b.

The third signal line TL3 may be disposed on one side of the pair of second subpixels SP2, and the fourth signal line TL4 may be disposed on another side of the pair of second subpixels SP2. For example, the third signal line TL3 may be disposed adjacent to the second signal line TL2. The third signal line TL3 may be electrically connected to the first electrode CE1 of one of the pair of second subpixels SP2, for example, the 2-1 subpixel SP2a. The fourth signal line TL4 may be electrically connected to the first electrode CE1 of the other of the pair of second subpixels SP2, for example, the 2-2 subpixel SP2b.

The fifth signal line TL5 may be disposed on one side of the pair of third subpixels SP3, and the sixth signal line TL6 may be disposed on another side of the pair of third subpixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one of the pair of third subpixels SP3, for example, the 3-1 subpixel SP3a. The sixth signal line TL6 may be electrically connected to the first electrode CE1 of the other of the pair of third subpixels SP3, for example, the 3-2 subpixel SP3b.

The plurality of signal lines TL may be formed of a conductive material. For example, the plurality of signal lines TL may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present specification are not limited thereto. For another example, the plurality of signal lines TL may be formed in a multi-layer structure of conductive materials. For example, the plurality of signal lines TL may be formed in a multi-layer structure of titanium (Ti)/aluminum (Al)/titanium (Ti)/indium tin oxide (ITO), but the embodiments of the present specification are not limited thereto.

The plurality of communication lines NL may be disposed in regions between the plurality of pixels PX. The plurality of communication lines NL may be disposed to extend in a row direction in the regions between the plurality of pixels PX. The plurality of communication lines NL may be disposed in regions between the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, and the like, but the embodiments of the present specification are not limited thereto.

According to the present specification, a bank BNK may be disposed in each of the plurality of subpixels. The plurality of banks BNK may be structures on which the plurality of light-emitting elements ED are seated. The plurality of banks BNK may guide positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNK may be bank patterns or structures, or the like, but the embodiments of the present specification are not limited thereto.

A bank BNK of the first subpixel SP1, a bank BNK of the second subpixel SP2, and a bank BNK of the third subpixel SP3 may disposed spaced apart from each other. The bank BNK of the first subpixel SP1, the bank BNK of the second subpixel SP2, and the bank BNK of the third subpixel SP3 may be configured to be separated. Accordingly, the banks BNK of the first subpixel SP1, the second subpixel SP2, and the third subpixel SP3 to which different types of light-emitting elements ED are transferred may be easily identified.

A bank BNK of the 1-1 subpixel SP1a and a bank BNK of the 1-2 subpixel SP1b may be connected to each other or may be formed to be spaced apart or separated from each other. For example, in consideration of the design of the transfer process requirements or the like, the bank BNK of the 1-1 subpixel SP1a and the bank BNK of the 1-2 subpixel SP1b where the same type of light-emitting elements ED are disposed may be connected to each other or may be spaced apart or separated from each other. Further, a bank BNK of the 2-1 subpixel SP2a and a bank BNK of the 2-2 subpixel SP2b may be connected to each other or may be formed to be spaced apart or separated from each other. A bank BNK of the 3-1 subpixel SP3a and a bank BNK of the 3-2 subpixel SP3b may be connected to each other, or may be formed to be spaced apart or separated from each other. Accordingly, the banks BNK of the pair of first subpixels SP1, the banks BNK of the pair of second subpixels SP2, and the banks BNK of the pair of third subpixels SP3 may be formed in various ways, and the embodiments of the present specification are not limited thereto.

For example, the plurality of banks BNK may be formed of an organic insulating material. The plurality of banks BNK may be formed of a single layer or multiple layers of an organic insulating material. For example, the plurality of banks BNK may be formed of a photoresist, a polyimide (PI)-based material, an acryl-based material, or the like, but the embodiments of the present specification are not limited thereto.

The first electrode CE1 may be disposed in each of the plurality of subpixels. The first electrode CE1 may be disposed on the bank BNK. The first electrode CE1 may be electrically connected to one of the plurality of signal lines TL. At least a portion of the first electrode CE1 may extend outside the bank BNK and may be electrically connected to the signal line TL most adjacent to the first electrode CE1. For example, a portion of the first electrode CE1 of the 1-1 subpixel SP1a may extend to one side region of the 1-1 subpixel SP1a and may be electrically connected to the first signal line TL1, and a portion of the first electrode CE1 of the 1-2 subpixel SP1b may extend to the other side region of the 1-2 subpixel SP1b and may be electrically connected to the second signal line TL2. A portion of the first electrode CE1 of the 2-1 subpixel SP2a may extend to one side region of the 2-1 subpixel SP2a and may be electrically connected to the third signal line TL3, and a portion of the first electrode CE1 of the 2-2 subpixel SP2b may extend to the other side region of the 2-2 subpixel SP2b and may be electrically connected to the fourth signal line TL4. A portion of the first electrode CE1 of the 3-1 subpixel SP3a may extend to one side region of the 3-1 subpixel SP3a and may be electrically connected to the fifth signal line TL5, and a portion of the first electrode CE1 of the 3-2 subpixel SP3b may extend to the other side region of the 3-2 subpixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. Different voltages may be applied to the first electrode CE1 of each of the plurality of subpixels depending on the image to be displayed. For example, different voltages may be applied to the first electrode CE1 of each of the plurality of subpixels. Accordingly, the first electrode CE1 may be a pixel electrode, but the embodiments of the present specification are not limited thereto.

The first electrode CE1 may be formed of a conductive material. For example, the first electrode CE1 may be integrally configured with the plurality of signal lines TL. For example, the first electrode CE1 may be formed of the same conductive material as the plurality of signal lines TL, but the embodiments of the present specification are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present specification are not limited thereto. For another example, the first electrode CE1 may be formed in a multi-layer structure of conductive materials. For example, the plurality of first electrodes CE1 may be formed in a multi-layer structure of titanium (Ti)/aluminum (Al)/titanium (Ti)/indium tin oxide (ITO), but the embodiments of the present specification are not limited thereto.

The light-emitting element ED may be disposed in each of the plurality of subpixels. The plurality of light-emitting elements ED may be any one of an LED and a micro LED, but the embodiments of the present specification are not limited thereto. The plurality of light-emitting elements ED may be disposed on the banks BNK and the first electrodes CE1. The plurality of light-emitting elements ED may be disposed on the first electrodes CE1 and may be electrically connected to the first electrodes CE1. Accordingly, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130 may be disposed in the first subpixel SP1. The second light-emitting element 140 may be disposed in the second subpixel SP2. The third light-emitting element 150 may be disposed in the third subpixel SP3. For example, one of the first light-emitting element 130, the second light-emitting element 140, and the third light-emitting element 150 may be a red light-emitting element, another may be a green light-emitting element, and the remaining one may be a blue light-emitting element, but the embodiments of the present specification are not limited thereto. Accordingly, various colors of light including white may be implemented by combining red light, green light, and blue light emitted from the plurality of light-emitting elements ED. The types of the plurality of light-emitting elements ED are exemplary, and the embodiments of the present specification are not limited thereto.

The first light-emitting element 130 may include a 1-1 light-emitting element 130a disposed in the 1-1 subpixel SP1a and a 1-2 light-emitting element 130b disposed in the 1-2 subpixel SP1b. The second light-emitting element 140 may include a 2-1 light-emitting element 140a disposed in the 2-1 subpixel SP2a and a 2-2 light-emitting element 140b disposed in the 2-2 subpixel SP2b. The third light-emitting element 150 may include a 3-1 light-emitting element 150a disposed in the 3-1 subpixel SP3a and a 3-2 light-emitting element 150b disposed in the 3-2 subpixel SP3b.

Referring to FIGS. 4 to 6, a second electrode CE2 may be disposed in each of the plurality of subpixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to a cathode electrode 135 of the light-emitting element ED to transmit a cathode voltage from the pixel driving circuit PD to the light-emitting element ED. The same cathode voltage may be applied to the second electrode CE2 of each of the plurality of subpixels. For example, the same voltage may be applied to the second electrode CE2 of each of the plurality of subpixels and the cathode electrode 135 of the light-emitting element ED. Accordingly, the second electrode CE2 may be a common electrode, but the embodiments of the present specification are not limited thereto.

At least some of the plurality of subpixels may share the second electrode CE2. At least some of the second electrodes CE2 of each of the plurality of subpixels may be electrically connected to each other. As the same voltage is applied to the second electrodes CE2, the second electrodes CE2 of at least some of the subpixels may be shared and used. For example, the second electrodes CE2 of at least some pixels PX of the plurality of pixels PX disposed in the same row may be connected to each other. For example, one second electrode CE2 may be disposed in the plurality of pixels PX. One second electrode CE2 may be disposed for every n subpixels.

For example, some of the second electrodes CE2 of each of the plurality of subpixels may be disposed to be spaced apart or separated from each other. For example, the second electrode CE2 connected to pixels PX in an nth row and the second electrode CE2 connected to pixels PX in an n+1th row may be disposed to be spaced apart or separated from each other. For example, the plurality of second electrodes CE2 may be disposed spaced apart from each other with the plurality of communication lines NL extending in the row direction therebetween. Accordingly, the number of subpixels may be greater than the number of second electrodes CE2. For another example, all the second electrodes CE2 of the plurality of subpixels may be connected to each other and thus only one second electrode CE2 may be disposed on the substrate 110, but the embodiments of the present specification are not limited thereto.

The plurality of second electrodes CE2 may be formed of a transparent conductive material, but the embodiments of the present specification are not limited thereto. The plurality of second electrodes CE2 may be formed of a transparent conductive material so that light emitted from the light-emitting element ED may be directed toward an upper portion of the second electrodes CE2. For example, the second electrode CE2 may be formed of a transparent conductive material such as indium tin oxide (ITO), indium zinc oxide (IZO), indium gallium zinc oxide (IGZO), or the like, but the embodiments of the present specification are not limited thereto.

The plurality of contact electrodes CCE may be disposed on the substrate 110. For example, the plurality of contact electrodes CCE may be disposed spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, when micro LEDs are used as the light-emitting elements ED, the display device 1000 may be manufactured by forming a plurality of micro LEDs on a wafer and transferring the micro LEDs to the substrate 110 of the display device 1000. In the process of transferring the plurality of light-emitting elements ED having a fine size from the wafer to the substrate 110, various defects may occur. For example, in some subpixels, a non-transfer defect in which the light-emitting element ED is not transferred may occur, and in other subpixels, a defect in which the light-emitting element ED is transferred to an incorrect position due to an alignment error may occur. Further, although the transfer process is normally performed, the transferred light-emitting element ED itself may be defective. Accordingly, in consideration of defects during the transfer process of the plurality of light-emitting elements ED, the plurality of light-emitting elements ED of the same type may be transferred to one subpixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together to one pixel PX and inspected for defects. When both the 1-1 light-emitting element 130a and the 1-2 light-emitting element 130b are determined to be normal, the 1-1 light-emitting element 130a may be used and the 1-2 light-emitting element 130b may not be used. For another example, when the 1-2 light-emitting element 130b is determined to be normal among the 1-1 light-emitting element 130a and the 1-2 light-emitting element 130b, the 1-1 light-emitting element 130a may not be used and only the 1-2 light-emitting element 130b may be used. Accordingly, even when the plurality of light-emitting elements ED of the same type are transferred to one pixel PX, ultimately, only one light-emitting element ED may be used.

Accordingly, one of the pair of light-emitting elements ED may be a main (or primary) light-emitting element ED and the other may be a redundancy light-emitting element ED. The redundancy light-emitting element ED may be a spare light-emitting element ED transferred to prepare for a defect of the main light-emitting element ED. When the main light-emitting element ED is defective, the redundancy light-emitting element ED may be used as a replacement. Accordingly, the deterioration of display quality due to the defects of the main light-emitting element ED and the redundancy light-emitting element ED may be minimized by transferring the main light-emitting element ED and the redundancy light-emitting element ED together to one pixel PX.

For example, the 1-1 light-emitting element 130a, the 2-1 light-emitting element 140a, and the 3-1 light-emitting element 150a transferred to one pixel PX may be used as the main light-emitting elements ED, and the 1-2 light-emitting element 130b, the 2-2 light-emitting element 140b, and the 3-2 light-emitting element 150b may be used as the redundancy light-emitting elements ED.

FIGS. 7 to 17 are plan views showing display devices according to embodiments of the present specification.

FIGS. 7 to 12 are partially enlarged views B1, B2, B3, B4, and B6 of portion B in FIG. 3, respectively. FIGS. 7 to 12 respectively show display devices according to a first embodiment to a sixth embodiment. Configurations that have substantially the same functions between the embodiments are denoted by the same reference numerals, and detailed descriptions thereof will be omitted.

Referring to FIGS. 7 to 12, the display device according to the first embodiment may include a display region AA and a first non-display region NA1. The display region AA may include a plurality of light-emitting elements 130, 140, and 150, a second electrode CE2, a first optical layer 117a, a second optical layer 117b, and a third optical layer 117c. The first non-display region NA1 may include the plurality of light-emitting elements 130, 140, and 150, the first optical layer 117a, the second optical layer 117b, and the third optical layer 117c.

The plurality of light-emitting elements 130, 140, and 150 disposed in the display region AA may emit light by a high potential power voltage applied to a first electrode as a plurality of second electrodes CE2 are disposed. The second electrodes CE2 may be formed to entirely cover a plurality of pixels to be common to the plurality of pixels. The second electrode CE2 may be formed to be common only to the plurality of light-emitting elements 130, 140, and 150 disposed in each pixel. However, the present specification is not limited thereto.

The plurality of light-emitting elements 130, 140, and 150 disposed in the display region AA and the first non-display region NA1 may include a first light-emitting element 130, a second light-emitting element 140, and a third light-emitting element 150. The first light-emitting element 130, the second light-emitting element 140, and the third light-emitting element 150 may respectively implement a first color, a second color, and a third color. The first to third colors may be any one of red, green, and blue selected so as not to overlap each other, but the embodiment of the present specification is not limited thereto. For example, the first color may be red, the second color may be green, and the third color may be blue, but the embodiments of the present specification are not limited thereto.

The first light-emitting element 130 may have a first size, the second light-emitting element 140 may have a second size, and the third light-emitting element 150 may have a third size. The first size may be different from the second size and/or the third size. The first size may be larger than the second size and/or the third size. As the first size of the first light-emitting element 130 which implements the first color is designed to be different from the second size of the second light-emitting element 140 and/or the third size of the third light-emitting element 150, the light efficiency of the display device may be enhanced.

The first non-display region NA1 may include a dummy region. The dummy region may include a dummy pixel including a plurality of dummy light-emitting elements. The second electrode CE2 may not be disposed in the first non-display region NA1 where the plurality of dummy light-emitting elements are disposed. Accordingly, even when a high potential power voltage is applied to the first electrode disposed on the dummy light-emitting elements, the dummy light-emitting elements may not emit light since the dummy light-emitting elements are not connected to the second electrode CE2.

Referring to FIG. 3 together, the first non-display region NA1 may include a region where a trench T is disposed. The region where the trench T is disposed may be formed to have substantially the same shape as the first non-display region NA1. For example, the first non-display region NA1 may have a rectangular shape whose four corners are formed in a round shape. In this case, the region where the trench T is disposed may have a rectangular shape whose four corners are formed in a round shape. An area of the rectangular shape formed by the outermost perimeter of the region where the trench T is disposed may be smaller than an area of the rectangular shape formed by the outermost perimeter of the first non-display region NA1. The region where the trench T is formed may be disposed to surround the display region AA. The region where the trench T is formed may be disposed to surround the plurality of pixels PX.

In one embodiment, the display region AA may include the region where the trench Tis formed. The region where the trench T is formed may be disposed to surround the plurality of pixels PX.

The trench T may be disposed to surround the plurality of pixels PX. At least a portion of the trench T may be disposed between the plurality of light-emitting elements 130, 140, and 150. The plurality of light-emitting elements 130, 140, and 150 may be disposed in the display region AA and/or the first non-display region NA1. The trench T may be disposed between the display region AA and a bending region BA. The trench T may be disposed between the display panel 100 and the bending region BA. The trench T may be disposed between at least a portion of the display panel 100 and the bending region BA.

Referring to FIG. 7, a first trench T1 may be disposed between the plurality of light-emitting elements 130, 140, and 150. The first trench T1 may be disposed to extend in a first direction (for example, an X-axis direction). The first trench T1 may be disposed between the first light-emitting element 130 and the second light-emitting element 140 (e.g., a pair of light-emitting elements) in the dummy region DUA, but the present specification is not limited thereto. Furthermore, the first trench T1 is disposed between at least one light-emitting element in the dummy region DUA (e.g., the second light-emitting element 140 in the dummy region DUA) and at least one light emitting element in the display region AA (e.g., the third light-emitting element 150 in the display region AA) as shown in FIG. 7. As the first trench T1 is disposed, the display panel may be protected from moisture penetration or the like from the outside. For example, since effects such as prevention of the moisture penetration and the like can be implemented, the reliability of the display device may be enhanced.

One pixel may include the first light-emitting element 130, the second light-emitting element 140, and the third light-emitting element 150. The third optical layer 117c may be disposed between the plurality of pixels disposed in the first direction (for example, the X-axis direction). For example, the third optical layer 117c may be disposed to extend in a second direction (for example, a Y-axis direction) intersecting the first direction.

The first optical layer 117a and the second optical layer 117b may be disposed to overlap a region where the pixels or dummy pixels are disposed in a planar direction (for example, in a Z-axis direction) of the display panel 100. The third optical layer 117c may be disposed between a plurality of first optical layers 117a or a plurality of second optical layers 117b (for example, in the X-axis direction).

In one embodiment, the first optical layer 117a may extend to one end (or one side) of the display panel. The second optical layer 117b may extend to the dummy region DUA where the dummy pixels are disposed without extending to the end of the display panel. The second optical layer 117b may be disposed on the first optical layer 117a. The second optical layer 117b may be disposed on the dummy pixels in the dummy region DUA. Accordingly, thicknesses of the optical layers 117a and 117b of the display panel 100 may decrease as it goes in the second direction (for example, the Y-axis direction). Ends (or one sides) of the second electrode CE2 and the second optical layer 117b in the first direction may be formed to meet at substantially the same point. The display region AA may include the second electrode CE2 and the second optical layer 117b.

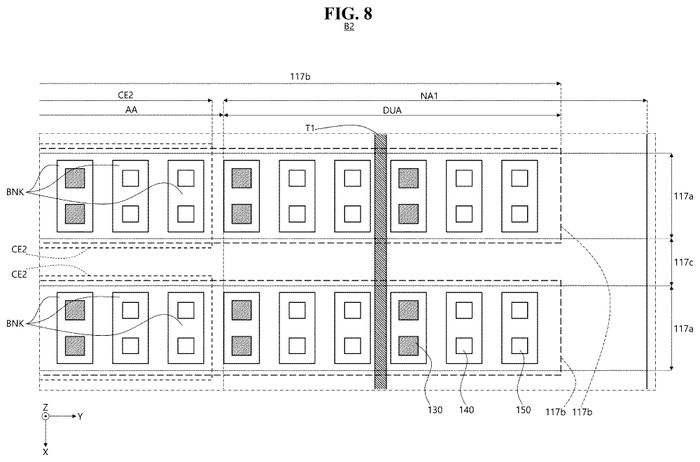

Referring to FIG. 8, in the display device according to the second embodiment, a first trench T1 may be disposed between a plurality of light-emitting elements 130, 140, and 150. The first trench T1 may be disposed to extend in the first direction (for example, the X-axis direction). The first trench T1 may be disposed between the third light-emitting element 150 and the first light-emitting element 130, but the present specification is not limited thereto. As the first trench T1 is disposed, the display panel 100 may be protected from moisture penetration or the like from the outside. For example, since effects such as prevention of the moisture penetration and the like can be implemented, the reliability of the display device 1000 may be enhanced.

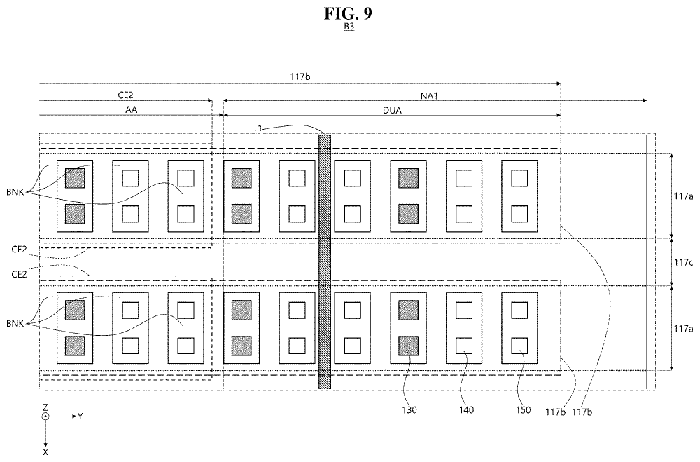

Referring to FIG. 9, in the display device according to the third embodiment, a first trench T1 may be disposed between a plurality of light-emitting elements 130, 140, and 150. The first trench T1 may be disposed to extend in the first direction (for example, the X-axis direction). The first trench T1 may be disposed between the second light-emitting element 140 and the third light-emitting element 150, but the present specification is not limited thereto. As the trench T is disposed between the second light-emitting element 140 and the third light-emitting element 150 having relatively small sizes, the design margin of the display panel may be secured. Accordingly, the probability of the defective transfer of the light-emitting element in the manufacturing process of the display panel may be reduced. Accordingly, the productivity of the display device may be enhanced.

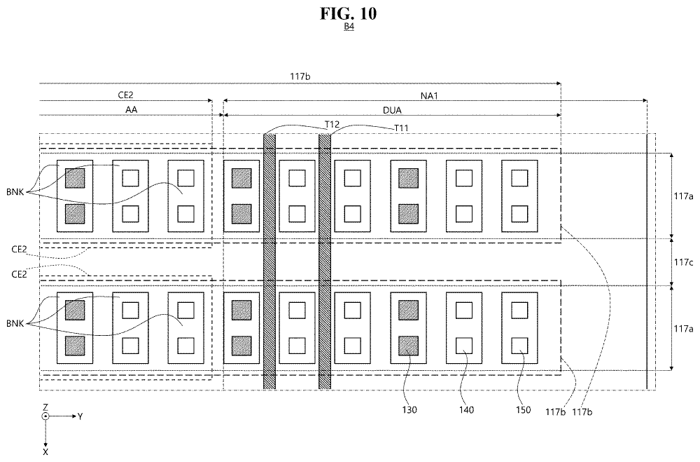

Referring to FIG. 10, in the display device according to the fourth embodiment, a 1-1 trench T11 (e.g., a first trench) and/or a 1-2 trench T12 (e.g., a second trench) may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between a first pair of light-emitting elements such as the second light-emitting element 140 and the third light-emitting element 150, and the 1-2 trench T12 may be disposed between a second pair of light-emitting elements such as the first light-emitting element 130 and the second light-emitting element 140, but the present specification is not limited thereto. As the trench is disposed between the second light-emitting element 140 and the third light-emitting element 150 having relatively small sizes, the design margin of the display panel may be secured. Further, as a plurality of trenches are disposed, effects such as prevention of the moisture penetration and the like can be further improved.

Referring to FIG. 11, in the display device according to the fifth embodiment, a 1-1 trench T11 (e.g., a first trench) and/or a 1-2 trench T12 (e.g., a second trench) may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between the second light-emitting element 140 and the third light-emitting element 150, and the 1-2 trench T12 may be disposed between a different second light-emitting element 140 and a different third light-emitting element 150, but the present specification is not limited thereto. As the trench T is disposed between the second light-emitting element 140 and the third light-emitting element 150 having relatively small sizes, the design margin of the display panel may be secured. Further, as a plurality of trenches are disposed, effects such as prevention of the moisture penetration and the like can be further improved.

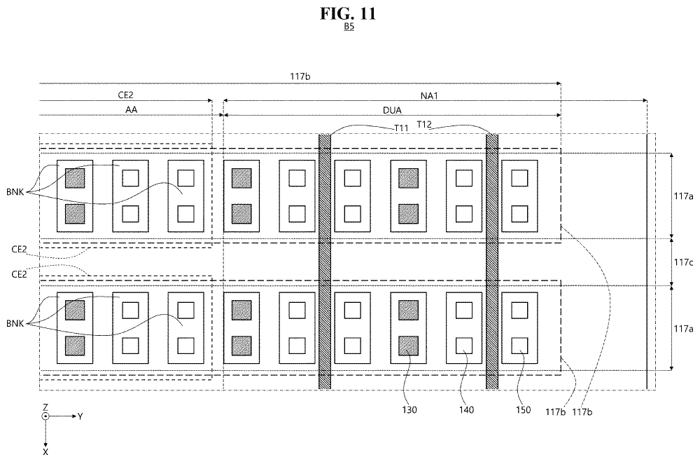

Referring to FIG. 12, in the display device according to the sixth embodiment, a 1-1 trench T11 (e.g., a first trench) and/or a 1-2 trench T12 (e.g., a second trench) may be disposed between a plurality of light-emitting elements 130, 140, and 150. The 1-1 trench T11 and/or the 1-2 trench T12 may be disposed to extend in the first direction (for example, the X-axis direction). The 1-1 trench T11 may be disposed between the second light-emitting element 140 and the third light-emitting element 150, and the 1-2 trench T12 may be disposed between the third light-emitting element 150 and the first light-emitting element 130 adjacent to each other, but the present specification is not limited thereto. As the trench is disposed between the second light-emitting element 140 and the third light-emitting element 150 having relatively small sizes, the design margin of the display panel may be secured. Further, as a plurality of trenches are disposed, effects such as prevention of the moisture penetration and the like can be further improved.

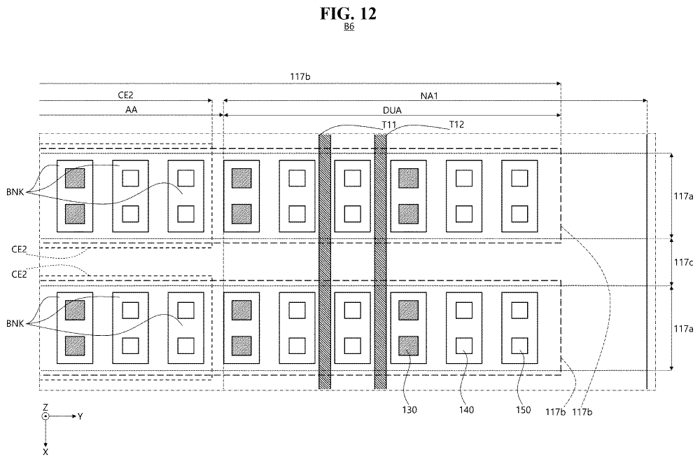

FIGS. 13 to 16 are partially enlarged views C1, C2, C3, and C4 of portion C in FIG. 3, respectively. FIGS. 13 to 16 respectively show display devices according to a seventh embodiment to a tenth embodiment. Configurations that are substantially the same as those in the above-described embodiment or between the embodiments are denoted by the same reference numerals, and detailed descriptions thereof will be omitted.

Referring to FIG. 13, the display device may include a round-shaped corner RE, but the embodiment of the present specification is not limited thereto. The round-shaped corner RE may include a 1-3 trench T13, a 1-4 trench T14, and a second trench T2 between the 1-3 trench T13 and the 1-4 trench T14. The 1-3 trench T13 and the 1-4 trench T14 may be disposed to extend in the first direction. The second trench T2 may be disposed to extend in the second direction intersecting the first direction. As shown, the first direction and the second direction are the X-axis direction and the Y-axis direction and intersect each other at a vertical angle, but the directions in which the 1-3 trench T13, the 1-4 trench T14, and the second trench T2 are disposed to extend are not limited thereto. For example, an arrangement angle of the trench may be set or adjusted.

The display device according to the seventh embodiment may include a display region AA and a first non-display region NA1.

A plurality of light-emitting elements 130, 140, and 150 disposed in the display region AA may emit light by a high potential power voltage applied to a first electrode as a plurality of second electrodes CE2 are disposed. The second electrode CE2 may be formed to correspond to a shape of the display region AA according to the round-shaped corner RE. For example, an area which covers the plurality of light-emitting elements 130, 140, and 150 may decrease as it goes in the first direction (for example, in the X-axis direction).

The first non-display region NA1 may include a dummy region DUA. The dummy region DUA may also be formed to correspond to the shape of the first non-display region NA1 according to the round-shaped corner RE. For example, an area which covers a plurality of dummy light-emitting elements may decrease as it goes in the first direction (for example, in the X-axis direction).

The 1-3 trench T13, the 1-4 trench T14, and the second trench T2 may be disposed between the plurality of light-emitting elements 130, 140, and 150 in the dummy region DUA. The 1-3 trench T13 may be disposed between a pair of light-emitting elements that are adjacent to each other within a same row of light-emitting elements along the second direction such as the first light-emitting element 130 and the second light-emitting element 140. The 1-4 trench T14 may be disposed in a dummy pixel disposed in the first direction (for example, X-axis direction) from the dummy pixel including the first light-emitting element 130 and the second light-emitting element 140 in which the 1-3 trench T13 is disposed. The 1-4 trench T14 may be disposed between another pair of light-emitting elements that are adjacent to each other in another row of light-emitting elements along the second direction such as the first light-emitting element 130 and the second light-emitting element 140. The second trench T2 may be disposed between a plurality of pixels. The second trench T2 may be disposed to extend in the second direction (for example, the Y-axis direction) intersecting the first direction between the dummy pixels disposed in the first direction (for example, X-axis direction). The second trench T2 may be disposed between the plurality of light-emitting elements 130, 140, and 150. The second trench T2 may be disposed between a pair of second light-emitting elements 140, between a pair of third light-emitting elements 150, or between a pair of first light-emitting elements 130 that each implement the same color and are disposed on different rows of light-emitting elements. Accordingly, the corner of the display panel may be protected. For example, effects such as moisture penetration and the like can be implemented. Accordingly, the reliability of the display device may be enhanced. The round-shaped corner RE is described in the embodiment of the present specification, but the present specification is not limited thereto. When the corner has a different shape, the trench disposed to correspond to the corner may be formed by changing the design of the above-described embodiment.

A first optical layer 117a, a second optical layer 117b, and a third optical layer 117c may be formed to correspond to a shape of the first non-display region NA1 according to the round-shaped corner RE. For example, a size of a region where the first optical layer 117a, the second optical layer 117b, and the third optical layer 117c overlap the display panel may decrease as it goes in the first direction. The second optical layer 117b may be disposed in the display region AA. Ends (or one sides) of the second electrode CE2 and the second optical layer 117b in the first direction may be formed to meet at substantially the same point. The display region AA may include the second electrode CE2 and the second optical layer 117b.

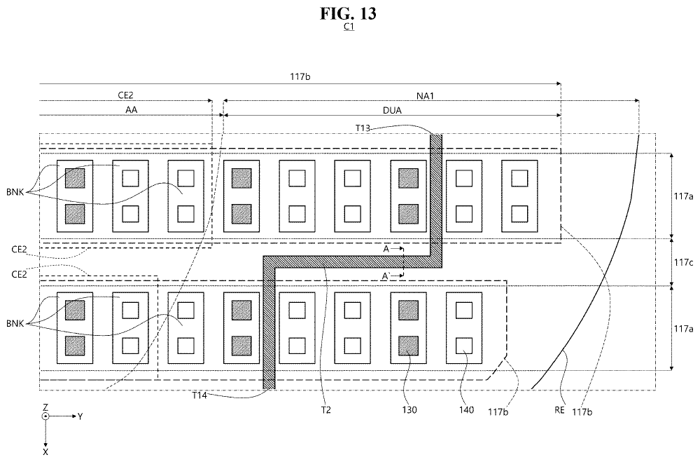

Referring to FIG. 14, in the display device according to the eighth embodiment, a 1-3 trench T13, a 1-4 trench T14, and a second trench T2 may be disposed between a plurality of light-emitting elements 130, 140, and 150 in the dummy region DUA. The 1-3 trench T13 may be disposed between the first light-emitting element 130 and the second light-emitting element 140. The 1-4 trench T14 may be disposed between the second light-emitting element 140 and the third light-emitting element 150. The second trench T2 may be disposed between a plurality of pixels. The second trench T2 may be disposed between the second light-emitting elements 140 or between the first light-emitting elements 130 that each implement the same color.

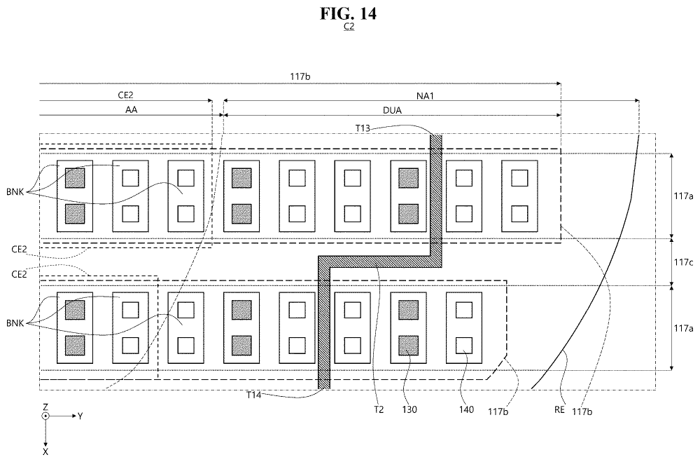

Referring to FIG. 15, in the display device according to the ninth embodiment, a 1-3 trench T13, a 1-4 trench T14, and a second trench T2 may be disposed between a plurality of light-emitting elements 130, 140, and 150 in the dummy region DUA. The 1-3 trench T13 may be disposed between the second light-emitting element 140 and the third light-emitting element 150. The 1-4 trench T14 may be disposed between the third light-emitting element 150 and the first light-emitting element 130 adjacent to each other. The second trench T2 may be disposed between a plurality of pixels. The second trench T2 may be disposed between the first light-emitting elements 130 or between the second light-emitting elements 140 that each implement the same color.

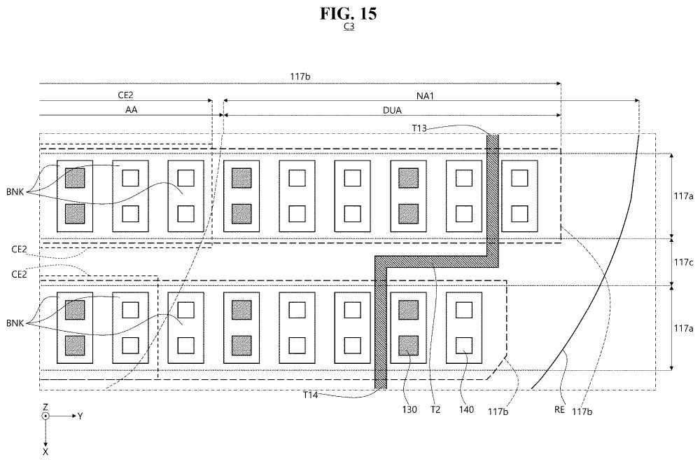

Referring to FIG. 16, according to the tenth embodiment, a 1-3 trench T13, a 1-4 trench T14, and a second trench T2 may be disposed between a plurality of light-emitting elements 130, 140, and 150 in the dummy region DUA. The 1-3 trench T13 may be disposed between the second light-emitting element 140 and the third light-emitting element 150. The 1-4 trench T14 may be disposed between the second light-emitting element 140 and the third light-emitting element 150. The second trench T2 may be disposed between a plurality of pixels. The second trench T2 may be disposed between the third light-emitting elements 150, between the first light-emitting elements 130, or between the second light-emitting elements 140 that each implement the same color.

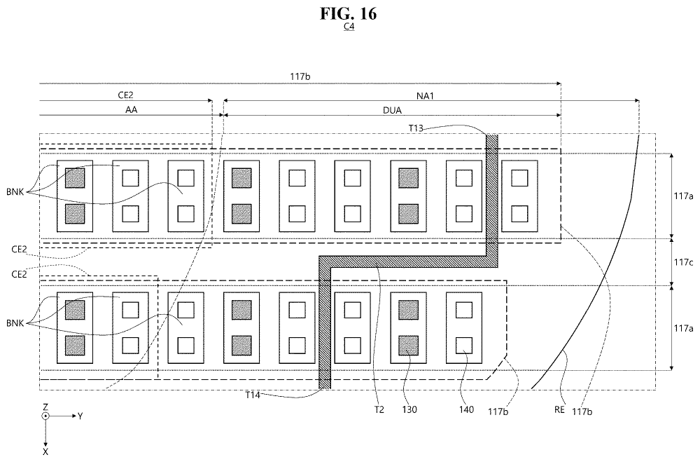

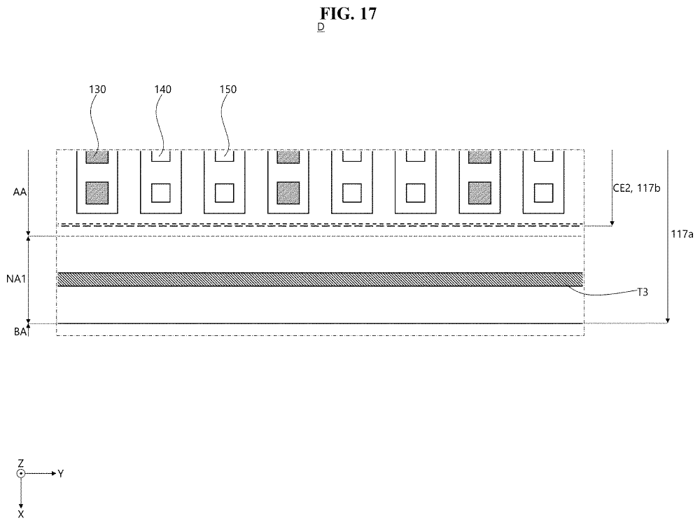

FIG. 17 is a partially enlarged view of portion D in FIG. 3. FIG. 17 shows a display device according to an eleventh embodiment.

Referring to FIG. 17, the display device according to the eleventh embodiment may include a display region AA and a first non-display region NA1. The display region AA may include a second electrode CE2 and a second optical layer 117b. Ends of the second electrode CE2 and the second optical layer 117b in the first direction may be formed to meet at substantially the same point.

The first non-display region NA1 may be disposed between a bending region BA and the display region AA. The first non-display region NA1 may include a third trench T3. The third trench T3 may be disposed to extend in the second direction intersecting the first direction. The third trench T3 may be disposed between the bending region BA and the display region AA. When the bending region BA is bent, an end of the first non-display region NA1 in the first direction may form one side of the display device. The third trench T3 may block moisture or the like from penetrating through the first direction in which the bending region BA is disposed. Accordingly, since the reliability of the display device may be enhanced, the lifespan of the display device may be extended.

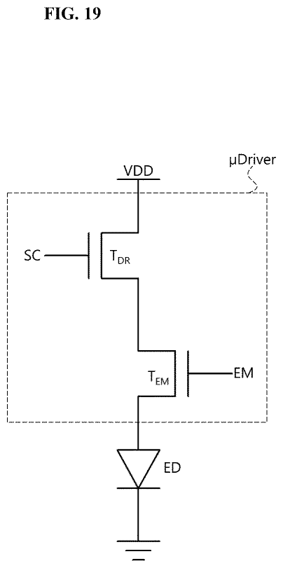

FIG. 19 is a view showing a circuit structure according to the embodiment of the present specification

In FIG. 19, an example in which one light-emitting element ED is connected to a micro driver μDriver is shown, but the present specification is not limited thereto. For example, 8 light-emitting elements ED may be connected to one micro driver μDriver. For another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

One micro driver μDriver may include a driving transistor TDR and a light-emitting transistor TEM, but the embodiments of the present specification are not limited thereto.

For example, in the driving transistor TDR, a high potential power voltage VDD may be applied to a first electrode of the driving transistor TDR, a first electrode of the light-emitting transistor TEM may be connected to a second electrode of the driving transistor TDR, and a scan signal SC may be applied to a gate electrode of the driving transistor TDR. The scan signal SC applied to the gate electrode of the driving transistor TDR is direct current power, and a fixed reference voltage may be applied for each frame, but the embodiments of the present specification are not limited thereto.

In the light-emitting transistor TEM, the second electrode of the driving transistor TDR may be connected to the first electrode of the light-emitting transistor TEM, the light-emitting element ED may be connected to a second electrode of the light-emitting transistor TEM, and an emission signal EM may be applied to a gate electrode of the light-emitting transistor TEM. The emission signal EM applied to the gate electrode of the light-emitting transistor TEM may be a pulse width modulation signal which varies for each frame, but the embodiments of the present specification are not limited thereto.

A first electrode of the light-emitting element ED may be connected to the second electrode of the light-emitting transistor TEM, and a second electrode of the light-emitting element ED may be connected to the ground. For example, the first electrode of the light-emitting element ED may be an anode electrode and the second electrode of the light-emitting element ED may be a cathode electrode, but the embodiments of the present specification are not limited thereto.

The driving transistor TDR and the light-emitting transistor TEM may each be an n-type transistor or a p-type transistor.

In the micro driver μDriver, the driving transistor TDR may be turned on by the scan signal SC applied from a timing controller, and the light-emitting transistor TEM may be turned on by the emission signal EM. Accordingly, as a driving current is applied to the light-emitting element ED via the driving transistor TDR and the light-emitting transistor TEM by the high potential power voltage VDD applied to the first electrode of the driving transistor TDR, the light-emitting element ED may emit light.

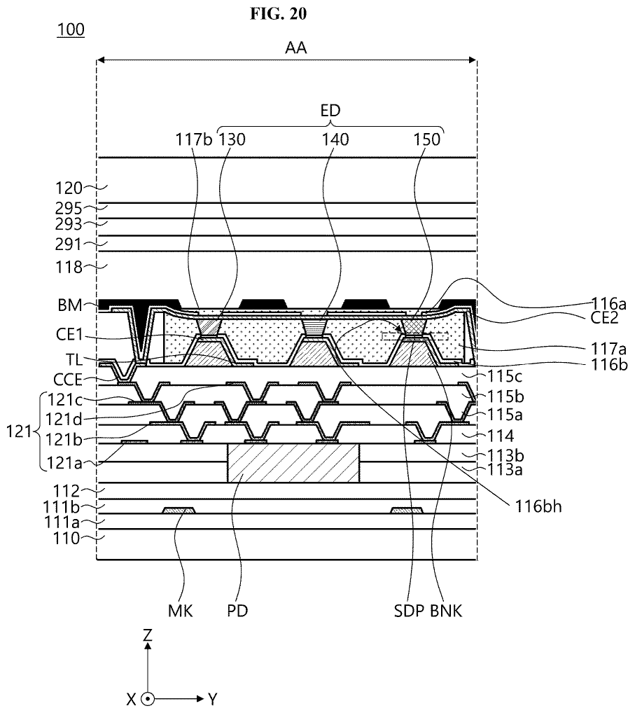

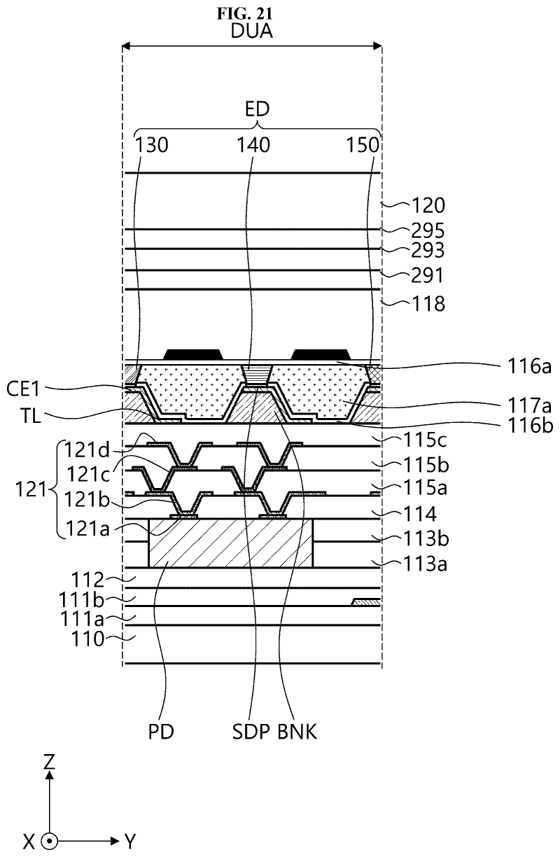

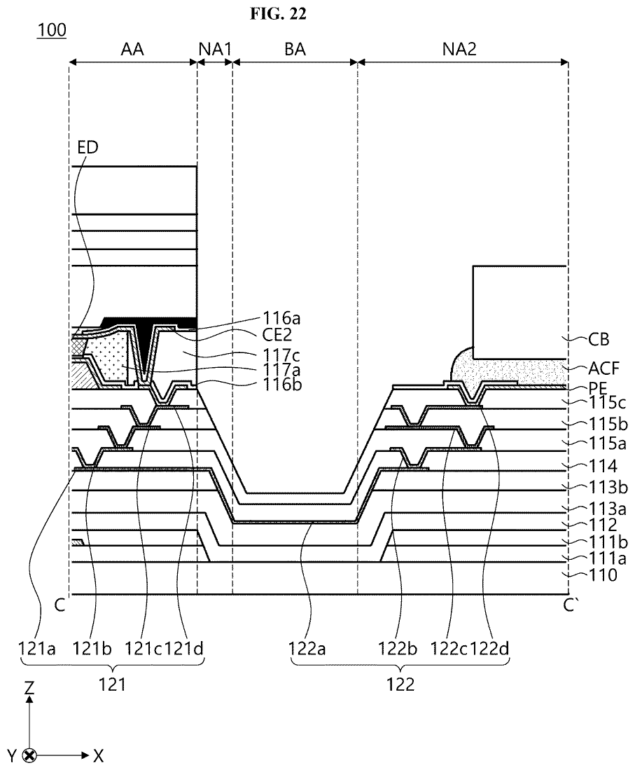

FIGS. 20 and 22 are cross-sectional views showing the display device according to the embodiment of the present specification. FIG. 21 is a cross-sectional view showing the display device according to the embodiment of the present specification.

FIGS. 20 and 22 are cross-sectional views of the display region AA, the first non-display region NA1, the bending region BA, and the second non-display region NA2. FIG. 22 is a cross-sectional view taken along line C-C′ in FIG. 18.

FIG. 21 is a cross-sectional view of the dummy region DUA. Configurations that are substantially the same between the cross-sectional views are denoted by the same reference numerals, and detailed descriptions thereof will be omitted.

Referring to FIGS. 20, 21, and 22, a first buffer layer 111a and a second buffer layer 111b may be disposed on the remaining region of the substrate 110 excluding the bending region BA.

The first buffer layer 111a and the second buffer layer 111b may be disposed in the display region AA, the first non-display region NA1, and the second non-display region NA2. The first buffer layer 111a and the second buffer layer 111b may reduce the penetration of moisture or impurities through the substrate 110. The first buffer layer 111a and the second buffer layer 111b may be formed of an inorganic insulating material. For example, the first buffer layer 111a and the second buffer layer 111b may be formed of a single layer or multiple layers of silicon oxide (SiOx) or silicon nitride (SiNx), but the embodiments of the present specification are not limited thereto.

For example, portions of the first buffer layer 111a and the second buffer layer 111b in the bending region BA may be removed. An upper surface of the substrate 110 located in the bending region BA may be exposed from the first buffer layer 111a and the second buffer layer 111b. Cracks in the first buffer layer 111a and the second buffer layer 111b which may occur during bending may be minimized by removing the first buffer layer 111a and the second buffer layer 111b formed of an inorganic insulating material from the bending region BA.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align the position of the pixel driving circuit PD transferred onto an adhesive layer 112. For another example, the plurality of alignment keys MK may be omitted.

The adhesive layer 112 may be disposed on the second buffer layer 111b. The adhesive layer 112 may be disposed in the display region AA, the first non-display region NA1, the bending region BA, and the second non-display region NA2. For another example, at least a portion of the adhesive layer 112 may be removed in the non-display region NA including the bending region BA. For example, the adhesive layer 112 may be formed of any one of an adhesive polymer, an epoxy resin, a UV-curable resin, a polyimide-based material, an acrylate-based material, a urethane-based material, and polydimethylsiloxane (PDMS), but the embodiments of the present specification are not limited thereto.

The pixel driving circuit PD may be disposed on the adhesive layer 112 in the display region AA. When the pixel driving circuit PD is implemented as a driving driver, the driving driver may be mounted on the adhesive layer 112 by a transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround the side surfaces of the pixel driving circuit PD, but the embodiments of the present specification are not limited thereto. For example, the second protective layer 113b may be disposed to cover at least a portion of an upper surface of the pixel driving circuit PD. For example, at least one of the first protective layer 113a and the second protective layer 113b disposed in the bending region BA may be omitted. For example, the first protective layer 113a may be entirely disposed in the display region AA and the non-display region NA, and the second protective layer 113b may be partially disposed in the display region AA, the first non-display region NA1, and the second non-display region NA2. For example, a portion of the second protective layer 113b in the bending region BA may be removed. However, the embodiments of the present specification are not limited thereto.

The first protective layer 113a and the second protective layer 113b may be formed of an organic insulating material, but the embodiments of the present specification are not limited thereto. For example, the first protective layer 113a and the second protective layer 113b may be formed of a photoresist, a polyimide (PI)-based material, a photo acrylic-based material, or the like, but the embodiments of the present specification are not limited thereto. For example, the first protective layer 113a and the second protective layer 113b may be overcoating layers or insulating layers, but the embodiments of the present specification are not limited thereto.

According to the present specification, a plurality of first connection lines 121 may be disposed on the second protective layer 113b in the display region AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, each of the 1-1 connection line 121a, the 1-2 connection line 121b, the 1-3 connection line 121c, and the 1-4 connection line 121d may be formed of a plurality of lines. The plurality of 1-1 connection line 121a may be spaced apart from each other and disposed on a same layer. The plurality of 1-2 connection line 121b may be spaced apart from each other and disposed on a same layer. The plurality of 1-3 connection line 121c may be spaced apart from each other and disposed on a same layer. The plurality of 1-4 connection line 121d may be spaced apart from each other and disposed on a same layer.

For example, the plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display region AA and the non-display region NA. The third protective layer 114 may cover side surfaces of the second protective layer 113b and an upper surface of the first protective layer 113a in the bending region BA. The third protective layer 114 may be formed of an organic insulating material. For example, the third protective layer 114 may be formed of a photoresist, a polyimide (PI)-based material, a photo acrylic-based material, or the like, but the embodiments of the present specification are not limited thereto. For example, the first protective layer 113a, the second protective layer 113b, and the third protective layer 114 may be formed of the same material. However, the embodiments of the present specification are not limited thereto. For example, the first protective layer 113a, the second protective layer 113b, and the third protective layer 114 may be insulating layers of different materials.

The plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through contact holes of the third protective layer 114. Other 1-2 connection lines 121b may be electrically connected to the 1-1 connection lines 121a through the contact holes of the third protective layer 114. However, the embodiments of the present specification are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display region AA and the non-display region NA, but the embodiments of the present specification are not limited thereto. The first insulating layer 115a may be formed of an organic insulating material, but the embodiments of the present specification are not limited thereto. For example, first insulating layer 115a may be formed of a photoresist, a polyimide (PI)-based material, a photo acrylic-based material, or the like, but the embodiments of the present specification are not limited thereto.

The plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining regions excluding the bending region BA, but the embodiments of the present specification are not limited thereto. The second insulating layer 115b may be disposed in the display region AA, the first non-display region NA1, and the second non-display region NA2, but the embodiments of the present specification are not limited thereto. For example, a portion of the second insulating layer 115b disposed in the bending region BA may be removed. The second insulating layer 115b may be formed of an organic insulating material, but the embodiments of the present specification are not limited thereto. For example, second insulating layer 115b may be formed of a photoresist, a polyimide (PI)-based material, a photo acrylic-based material, or the like, but the embodiments of the present specification are not limited thereto.

The plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

According to the present specification, the plurality of connection lines 121 may be formed of titanium (Ti)/aluminum (Al)/titanium (Ti), but the embodiments of the present specification are not limited thereto.

According to the present specification, the plurality of connection lines 121 may be disposed on different layers to be offset from each other with the plurality of insulating layers 115 therebetween. The plurality of connection lines 121 may be disposed in a step shape or a zigzag shape with the plurality of insulating layers 115 therebetween. For example, the plurality of 1-2 connection lines 121b may be disposed on a different layer from the plurality of 1-3 connection lines 121c with the first insulating layer 115a therebetween. The plurality of 1-2 connection lines 121b may be disposed to be offset from the plurality of 1-3 connection lines 121c with the first insulating layer 115a therebetween. For example, the plurality of 1-3 connection lines 121c may be disposed on a different layer from the plurality of 1-4 connection lines 121d with the second insulating layer 115b therebetween. The plurality of 1-3 connection lines 121c may be disposed to be offset from the plurality of 1-4 connection lines 121d with the second insulating layer 115b therebetween. Accordingly, since the plurality of connection lines 121 are disposed on different layers to be offset from each other with the plurality of insulating layers 115 therebetween, moisture may be prevented from penetrating into the plurality of connection lines 121. Further, the oxidation of aluminum (Al) in the titanium (Ti)/aluminum (Al)/titanium (Ti) structure that constitutes the plurality of connection lines 121 due to moisture penetration into the plurality of connection lines 121 may be prevented, and corrosion of the plurality of connection lines 121 due to the oxidation of aluminum (Al) may be prevented.

According to the present specification, a plurality of second connection lines 122 may be disposed on the second protective layer 113b in the non-display region NA. The plurality of second connection lines 122 may be lines for transmitting signals transmitted from the flexible circuit board (or flexible film) CB and the printed circuit board 160 (see in FIG. 1) to the pad portion PAD to the pixel driving circuit PD of the display region AA. For example, the plurality of second connection lines 122 may be electrically connected to the plurality of pad electrodes PE to receive signals from the flexible circuit board (or flexible film) CB and the printed circuit board 160.

For example, the plurality of second connection lines 122 may extend from the pad portion PAD toward the display region AA and transmit the signals to lines in the display region AA. The plurality of second connection lines 122 may be may electrically connect the plurality of pad electrodes PE and one or more pixel driving circuits PD. In this case, the plurality of second connection lines 122 may function as link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display region NA2 to the bending region BA and the first non-display region NA1. The 2-1 connection line 122a may be disposed on a same layer as the 1-1 connection line 121a, which is disposed on the one or more pixel driving circuits PD from the plurality of first connection lines 121. The plurality of 2-1 connection lines 122a may transmit signals transmitted from the flexible circuit board (or flexible film) CB and the printed circuit board to the pad portion PAD to the pixel driving circuit PD of the display region AA.

A plurality of 2-2 connection lines 122b may be disposed on the third protective layer 114. The plurality of 2-2 connection lines 122b may be disposed in the second non-display region NA2. The 2-2 connection lines 122b may be electrically connected to the 2-1 connection lines 122a through contact holes of the third protective layer 114. Accordingly, the signals from the flexible circuit board (or flexible film) CB and the printed circuit board 160 may be transmitted to the 2-1 connection lines 122a through the 2-2 connection lines 122b.

The 2-3 connection line 122c may be disposed on the first insulating layer 115a. The 2-3 connection line 122c may be disposed in the second non-display region NA2. The 2-3 connection line 122c may be electrically connected to the 2-2 connection lines 122b through a contact hole of the first insulating layer 115a. Accordingly, the signals from the flexible circuit board (or flexible film) CB and the printed circuit board 160 may be transmitted to the 2-1 connection lines 122a through the 2-3 connection line 122c and the 2-2 connection lines 122b.

The 2-4 connection line 122d may be disposed on the second insulating layer 115b. The 2-4 connection line 122d may be disposed in the second non-display region NA2. The 2-4 connection line 122d may be electrically connected to the 2-3 connection line 122c through a contact hole of the second insulating layer 115b. Accordingly, the signals from the flexible circuit board (or flexible film) CB and the printed circuit board 160 may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a conductive material having excellent flexibility or any one of various conductive materials used in the display region AA. For example, the second connection line 122 partially disposed in the bending region BA may be formed of a conductive material having excellent flexibility such as gold (Au), silver (Ag), aluminum (Al), or the like, but the embodiments of the present specification are not limited thereto. For another example, the plurality of first connection lines 121 and the plurality of second connection lines 122 may be formed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present specification are not limited thereto.

A third insulating layer 115c may be disposed on the plurality of first connection lines 121 and the plurality of second connection lines 122. The third insulating layer 115c may be disposed in the remaining regions excluding the bending region BA, but the embodiments of the present specification are not limited thereto. The third insulating layer 115c may be disposed in the display region AA, the first non-display region NA1, and the second non-display region NA2. A portion of the third insulating layer 115c disposed in the bending region BA may be removed. The third insulating layer 115c may be formed of an organic insulating material, but the embodiments of the present specification are not limited thereto. For example, the third insulating layer 115c may be formed of a photoresist, a polyimide (PI)-based material, a photo acrylic-based material, or the like, but the embodiments of the present specification are not limited thereto.

The plurality of banks BNK may be disposed on the third insulating layer 115c in the display region AA. The plurality of banks BNK may be disposed to overlap the plurality of subpixels, respectively. One or more light-emitting elements ED of the same type may be disposed on each of the plurality of banks BNK.

The plurality of signal lines TL may be disposed on the third insulating layer 115c in the display region AA. The plurality of signal lines TL may be disposed in regions between the plurality of banks BNK. For example, the plurality of signal lines TL may be disposed adjacent to any one of the plurality of banks BNK.

The plurality of contact electrodes CCE may be disposed on the third insulating layer 115c in the display region AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

The first optical layer 117a may be disposed around the plurality of light-emitting elements ED in the display region AA. For example, the first optical layer 117a may surround the plurality of light-emitting elements ED. For example, the first optical layer 117a may be disposed to cover the plurality of light-emitting elements ED and the bank BNK in regions of the plurality of subpixels. For example, the first optical layer 117a may cover the bank BNK, a portion of a second passivation layer 116b, and a space between the plurality of light-emitting elements ED. The first optical layer 117a may be disposed between the plurality of light-emitting elements ED included in one pixel PX and between the plurality of banks BNK or may cover spaces between the plurality of light-emitting elements ED and between the plurality of banks BNK. For example, the first optical layers 117a may extend in the first direction (X) and may be disposed spaced apart from each other in the second direction (Y). For example, the first optical layer 117a may be disposed between the second passivation layer 116b and the second electrode CE2 to surround side portions of the light-emitting element ED and the bank BNK, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be formed of siloxane in which fine metal particles such as titanium dioxide (TiO2) particles are dispersed, but the embodiments of the present specification are not limited thereto. Light from the plurality of light-emitting elements ED may be scattered by the fine particles dispersed in the first optical layer 117a and emitted to the outside of the display device 1000. Accordingly, the first optical layer 117a may enhance the extraction efficiency of the light emitted from the plurality of light-emitting elements ED.

For example, the first optical layer 117a may be disposed in each of the plurality of pixels PX or may be disposed together in some of the pixels PX disposed in the same row, but the embodiments of the present specification are not limited thereto. For example, the first optical layer 117a may be disposed in each of the plurality of pixels PX, or the plurality of pixels PX may share one first optical layer 117a. For another example, each of the plurality of subpixels may separately include the first optical layer 117a, but the embodiments of the present specification are not limited thereto.

Referring to the plan view according to above-described FIGS. 7 to 16, the third optical layer 117c may be disposed between the first optical layers 117a. The third optical layer 117c may be disposed on the second passivation layer 116b in the display region AA. For example, the third optical layer 117c may be present around the first optical layer 117a. For example, the third optical layer 117c may be disposed to surround the first optical layer 117a. For example, the third optical layer 117c may be in contact with a side surface of the first optical layer 117a. For example, the third optical layer 117c may be disposed in the region between the plurality of pixels PX. However, the embodiments of the present specification are not limited thereto. For example, the third optical layer 117c may be a diffusion layer, a diffusion layer window, a window diffusion layer, or the like, but the embodiments of the present specification are not limited thereto.

The third optical layer 117c may be formed of an organic insulating material, but the embodiments of the present specification are not limited thereto. The third optical layer 117c may be formed of the same material as the first optical layer 117a, but the embodiments of the present specification are not limited thereto. For example, the first optical layer 117a may include fine particles, and the third optical layer 117c may not include fine particles. For example, the third optical layer 117c may be formed of siloxane, but the embodiments of the present specification are not limited thereto.

For example, a thickness of the first optical layer 117a may be less than a thickness of the third optical layer 117c, but the embodiments of the present specification are not limited thereto. Accordingly, when viewed in a plan view, a region where the first optical layer 117a is disposed may include a concave portion recessed inward from an upper surface of the third optical layer 117c.

According to the present specification, the second electrode CE2 may be disposed on the first optical layer 117a and the third optical layer 117c. For example, the second electrode CE2 may be electrically connected to the plurality of contact electrodes CCE through contact holes of the third optical layer 117c. For example, the second electrode CE2 may be disposed on the plurality of light-emitting elements ED. For example, the second electrode CE2 may include a transparent conductive oxide such as indium tin oxide (ITO), indium zinc oxide (IZO), or the like, but the embodiments of the present specification are not limited thereto. For example, the second electrode CE2 may be disposed to be in contact with the cathode electrode 135. For example, the second electrode CE2 may overlap the first optical layer 117a. For example, the second electrode CE2 may cover an outer flat surface of the first optical layer 117a.

The second electrode CE2 may continuously extend in the first direction (X) of the substrate 110. Accordingly, the second electrode CE2 may be connected to the plurality of pixels PX arranged in the first direction (X) of the substrate 110, in common. For example, the second electrode CE2 may be connected to the plurality of pixels PX in common.

According to the present specification, the second electrode CE2 may continuously extend on the first optical layer 117a, the third optical layer 117c, and the light-emitting element ED. The region where the first optical layer 117a is disposed may include the concave portion recessed inward from the upper surface of the third optical layer 117c. Accordingly, a first portion of the second electrode CE2 disposed on the first optical layer 117a is disposed along the concave portion, and thus may be disposed at a lower position than a second portion of the second electrode CE2 disposed on the third optical layer 117c.

The second optical layer 117b may be disposed on the second electrode CE2. The second optical layer 117b may be disposed to overlap the plurality of light-emitting elements ED and the first optical layer 117a. Since the second optical layer 117b is disposed on the second electrode CE2 and the plurality of light-emitting elements ED, the stain (mura) which may occur over some of the plurality of light-emitting elements ED may be improved. For example, when the plurality of light-emitting elements ED are transferred onto the substrate 110 of the display device 1000, a region where intervals between the plurality of light-emitting elements ED are not uniform may occur due to a process deviation or the like. When the intervals between the plurality of light-emitting elements ED are not uniform, a light-emitting region of each of the plurality of light-emitting elements ED may be disposed non-uniformly, and the stain (mura) may be visible to the user. Accordingly, since the second optical layer 117b is configured to uniformly diffuse light over the plurality of light-emitting elements ED, it is possible to reduce the light emitted from some of the light-emitting elements ED from being visible to the user as stain (mura). Accordingly, since the light emitted from the plurality of light-emitting elements ED is uniformly diffused by the second optical layer 117b and extracted to the outside of the display device 1000, the brightness uniformity of the display device 1000 may be enhanced.

The second optical layer 117b may be formed of an organic insulating material in which fine particles are dispersed, but the embodiments of the present specification are not limited thereto. For example, the second optical layer 117b may be formed of siloxane in which fine metal particles such as titanium dioxide (TiO2) particles are dispersed, but the embodiments of the present specification are not limited thereto. For example, the second optical layer 117b may be formed of the same material as the first optical layer 117a, but the embodiments of the present specification are not limited thereto. For example, the second optical layer 117b may be a diffusion layer or an upper surface diffusion layer, but the embodiments of the present specification are not limited thereto.

According to the present specification, light from the plurality of light-emitting elements ED may be scattered by the fine particles dispersed in the second optical layer 117b and emitted to the outside of the display device 1000. The second optical layer 117b may uniformly mix the light emitted from the plurality of light-emitting elements ED to further enhance the brightness uniformity of the display device 1000. Further, the light extraction efficiency of the display device 1000 may be enhanced by the light scattered from the plurality of fine particles, and accordingly, the display device 1000 may be driven at low power.

According to the present specification, a first passivation layer 116a may be disposed on the first optical layer 117a such that the first passivation layer 116a is farther from the substrate 110 than the first optical layer 117a. Alternatively, the first passivation layer 116a may be disposed on the second optical layer 117b. Alternatively, the first passivation layer 116a may be disposed on the third optical layer 117c. For example, the first passivation layer 116a may be disposed in the display region AA and the first non-display region NA1. Since the first passivation layer 116a is disposed to cover the first optical layer 117a, the second optical layer 117b, or the third optical layer 117c disposed in the display region AA and the first non-display region NA1, the penetration of moisture or impurities into the first optical layer 117a, the second optical layer 117b, or the third optical layer 117c may be reduced. For example, the first passivation layer 116a may be formed of a single or multiple layers of silicon oxide (SiOx) or silicon nitride (SiNx), but the embodiments of the present specification are not limited thereto. For example, the first passivation layer 116a may be a protective layer or an insulating layer, but the embodiments of the present specification are not limited thereto.

A thickness of the first passivation layer 116a may be greater than a thickness of the second passivation layer 116b, but the embodiments of the present specification are not limited thereto. Since the first optical layer 117a is formed of a material in which fine particles are dispersed, the stain (mura) may occur due to the diffusion of the fine particles when forming the first optical layer 117a. Accordingly, the stain caused by the first optical layer 117a may be prevented or reduced by the first passivation layer 116a. Further, as the thickness of the first passivation layer 116a becomes greater than the thickness of the second passivation layer 116b, the stain caused by the first optical layer 117a may be prevented or reduced. For example, the thickness of the first passivation layer 116a may be 3,000 Å to 5,000 Å, but the embodiments of the present specification are not limited thereto. For example, the thickness of the second passivation layer 116b may be 500 Å to 1500 Å. Alternatively, the thickness of the second passivation layer 116b may be 800 Å to 1200 Å. However, the embodiments of the present specification are not limited thereto.

A black matrix BM may be disposed on the second electrode CE2, the first optical layer 117a, the third optical layer 117c, and the second optical layer 117b in the display region AA. For example, the black matrix BM may fill a contact hole of the third optical layer 117c. The black matrix BM may be configured to cover the display region AA, and thus may reduce the color mixing of light of the plurality of subpixels and external light reflection. For example, the black matrix BM may also be disposed in the contact hole through which the second electrode CE2 and the contact electrode CCE are connected, and thus may prevent light leakage between the plurality of neighboring subpixels.

For example, the black matrix BM may be formed of an opaque material, but the embodiments of the present specification are not limited thereto. For example, the black matrix BM may be an organic insulating material to which a black pigment or black dye is added, but the embodiments of the present specification are not limited thereto.

A cover layer 118 may be disposed on the black matrix BM in the display region AA. The cover layer 118 may protect the configurations under the cover layer 118. For example, the cover layer 118 may be formed an organic insulating material, but the embodiments of the present specification are not limited thereto. For example, the cover layer 118 may be formed of a photoresist, a polyimide (PI)-based material, a photo acrylic-based material, or the like, but the embodiments of the present specification are not limited thereto. For example, the cover layer 118 may be an overcoating layer or an insulating layer, but the embodiments of the present specification are not limited thereto.

The polarization layer 293 may be disposed on the cover layer 118 via a first adhesive layer 291. The cover member 120 may be disposed on the polarization layer 293 via the second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present specification are not limited thereto.

According to the present specification, the plurality of pad electrodes PE may be disposed on the third insulating layer 115c in the second non-display region NA2. For example, at least portions of the plurality of pad electrodes PE may be exposed from the second passivation layer 116b. For example, the plurality of pad electrodes PE may be electrically connected to the 2-4 connection lines 122d through contact holes of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present specification are not limited thereto. When heat or pressure is applied to the adhesive layer ACF, since the conductive balls may be electrically connected at a portion to which the heat or pressure is applied, the adhesive layer ACF may have conductive properties. The flexible circuit board (or flexible film) CB may be attached or bonded to the plurality of pad electrodes PE by disposing the adhesive layer ACF between the plurality of pad electrodes PE and the flexible circuit board (or flexible film) CB. For example, the adhesive layer ACF may be an anisotropic conductive film (ACF), but the embodiments of the present specification are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Accordingly, the signals output from the flexible circuit board (or flexible film) CB and the printed circuit board 160 may be transmitted to the pixel driving circuit PD of the display region AA through the plurality of pad electrodes PE, the 2-4 connection line 122d, the 2-3 connection line 122c, the 2-2 connection line 122b, and the 2-1 connection line 122a.

Referring to FIG. 21, the first electrode CE1 and the plurality of light-emitting elements 130, 140, and 150 may be disposed in the dummy region DUA. The second electrode CE2 may not be disposed in the dummy region DUA. Thus, the dummy region DUA lacks the second electrode CE2. Accordingly, in the dummy region DUA, the cathode voltage is not supplied through the second electrode CE2, and the light-emitting elements 130, 140, and 150 cannot emit light. Further, the second optical layer 117b may not be disposed in the dummy region DUA, but the present specification is not limited thereto.

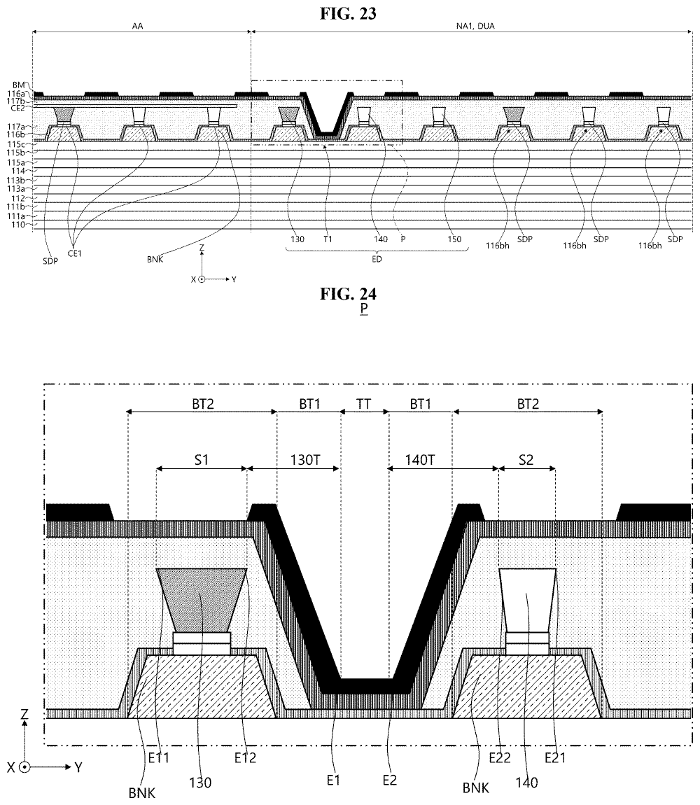

FIGS. 23 to 28 are cross-sectional views showing the display devices according to the embodiment of the present specification. Configurations that have substantially the same functions as those in the above-described embodiments are denoted by the same reference numerals, and detailed descriptions thereof will be omitted.

FIG. 23 is a cross-sectional view corresponding to the display device according to the first embodiment. FIG. 24 is a partially enlarged view of portion P in FIG. 23.

Referring to FIGS. 23 and 24, the display device may include the plurality of light-emitting elements 130, 140, and 150 disposed in the display region AA and the first non-display region NA1. For example, the first optical layer 117a may be disposed between the plurality of light-emitting elements 130, 140, and 150 disposed in the display region AA and the first non-display region NA1. The first optical layer 117a may be present around the plurality of light-emitting elements ED in the display region AA and the first non-display region NA1. For example, the first optical layer 117a may surround the plurality of light-emitting elements ED disposed in the display region AA and the first non-display region NA1. The second optical layer 117b may be disposed on the first optical layer 117a in the display region AA and the first non-display region NA1. The second optical layer 117b may be disposed in the display region AA and the dummy region DUA. In a region where the second optical layer 117b is not disposed in the first non-display region NA1, a thickness (for example, a length in the Z-axis direction) formed by the optical layer may be lower than that in the dummy region DUA.

The first passivation layer 116a may be disposed on the first optical layer 117a in the dummy region DUA. The first passivation layer 116a may be disposed on the second optical layer 117b in the display region AA. The first passivation layer 116a may be formed in at least a portion of the display region AA and the first non-display region NA1. The first passivation layer 116a may be formed to cover the display region AA and the first non-display region NA1 on the first optical layer 117a and/or the second optical layer 117b. For example, the first passivation layer 116a may be formed to entirely cover the display region AA and the first non-display region NA1 on the first optical layer 117a and/or the second optical layer 117b. For example, the first passivation layer 116a may be entirely disposed over the display region AA and the first non-display region NA1. Since the display device 1000 according to the embodiment of the present specification includes the first passivation layer 116a and the first trench T1, moisture penetration from the outside of the display device may be prevented, and thus the lifespan of the display device may be enhanced. Accordingly, a display device which has reduced power consumption and may be driven with low power may be provided.

According to the present specification, the first optical layer 117a and/or the second optical layer 117b may be protected by the first passivation layer 116a. Accordingly, since the display device may be protected from moisture penetration from the outside, the reliability of the display device may be enhanced.

The second passivation layer 116b may be formed to cover the banks BNK on which the plurality of light-emitting elements 130, 140, and 150 are disposed. The second passivation layer 116b may include a hole 116bh which exposes the solder pattern SDP. Since the display device according to the embodiment of the present specification further includes the first passivation layer 116a which protects the first optical layer 117a and/or the second optical layer 117b in addition to the second passivation layer 116b which protects a lower portion of the bank BNK, the display device may be protected from external moisture or the like, and accordingly, the lifespan of the display device may be extended.

Referring to FIG. 23, the display device includes the first trench T1. Referring to the coordinate system, the first trench T1 may be disposed to extend in the first direction (for example, the X-axis direction). The non-display region NA may include the first trench T1. The dummy region DUA may include the first trench T1. The first trench T1 may be formed between the plurality of light-emitting elements 130, 140, and 150. The first trench T1 may be formed between the plurality of dummy light-emitting elements (the plurality of light-emitting elements disposed in the dummy region DUA).

For example, when the thickness of the first passivation layer 116a is too thick, a warpage phenomenon may occur in a portion where the first trench T1 is present. Further, since a deposition time, a time required for an etching process (for example, a dry etching process), and/or the like increase, a turn around time (TAT) may increase.

For example, when the thickness of the first passivation layer 116a is too thin, there is a problem in that fine particles included in the first optical layer 117a in a portion of the first trench T1 where a slope is formed are not fixed to the corresponding slope surface.

In one embodiment, the thickness of the first passivation layer 116a may be in a range of 3,000 Å to 5,000 Å, but the embodiments of the present specification are not limited thereto. Accordingly, there is an advantage in that the warpage phenomenon may be prevented and the fine particles may be efficiently fixed to the slope surface.

For example, when the width of the first trench T1 is too short, since a slope angle of the first trench T1 becomes too high, the first passivation layer 116a may not be formed or deposited in the first trench T1.

For example, when the width of the first trench T1 is too long, after the light-emitting elements ED are transferred and the first optical layer 117a is formed or deposited, the first optical layer 117a may not protect the light-emitting elements ED. Accordingly, the light-emitting elements ED may not be properly fixed or formed and may be lost in a subsequent process.

The first optical layer 117a formed in the first non-display region NA1 and/or the dummy region DUA may include the first trench T1. The second optical layer 117b formed in the first non-display region NA1 and/or the dummy region DUA may include the first trench T1. As at least a portion of the first optical layer 117a and/or the second optical layer 117b is removed, the first trench T1 may be formed. Thus, the first trench T1 extends through each of the first optical layer 117a and the second optical layer 117b. The first trench T1 may extend through each of the first optical layer 117a and the second optical layer 117b in the dummy region DUA. The first passivation layer 116a may be disposed in the first trench T1. At least a portion of the black matrix BM may be disposed in the first trench T1.

Referring to FIG. 24, the first trench T1 may include a first end E1 and a second end E2 facing each other. The first light-emitting element 130 may include a 1-1 end E11 (e.g., a first end) that is relatively far from the first end E1 and a 1-2 end E12 (e.g., a second end) relatively close to the first end E1. The second light-emitting element 140 may include a 2-1 end E21 (e.g., a first end) relatively far from the second end E2 and a 2-2 end E22 (e.g., a second end) relatively close to the second end E2. For example, the end may be one side, but the present specification is not limited thereto.

A distance BT1 between the first end E1 of the first trench T1 and one end (or one side) of the bank BNK on which the first light-emitting element 130 is disposed and a distance BT1 between the second end E2 of the first trench T1 and one end (or one side) of the bank BNK on which the second light-emitting element 140 is disposed may be substantially the same. A distance BT2 between one end (or one side) and the other end (or the other side) of the bank BNK on which the first light-emitting element 130 is disposed and a distance BT2 between one end (or one side) and the other end (or the other side) of the bank BNK on which the second light-emitting element 140 is disposed may be substantially the same. A distance TT between the first end E1 and the second end E2 of the first trench T1 may be less than the distance BT1 between the first end E1 or the second end E2 and one end (or one side) of the bank BNK on which the light-emitting element is disposed. The distance TT between the first end E1 and the second end E2 may be less than the distance BT2 between one end (or one side) and the other end (or the other side) of the bank BNK on which the light-emitting element is disposed.

The first light-emitting element 130 may have a first size. The first size may be proportional to a distance S1 between the 1-1 end E11 and the 1-2 end E12. The second light-emitting element 140 may have a second size. The second size may be proportional to a distance S2 between the 2-1 end E21 and the 2-2 end E22. The second size may be different from the first size. The second size may be smaller than the first size. Since the first size is formed relatively large, the light efficiency of the first light-emitting element 130 may be enhanced. Since the first size is formed relatively larger than the second size, a distance 130T between the first end E1 and the 1-2 end E12 may be less than a distance 140T between the second end E2 and the 2-2 end E22.

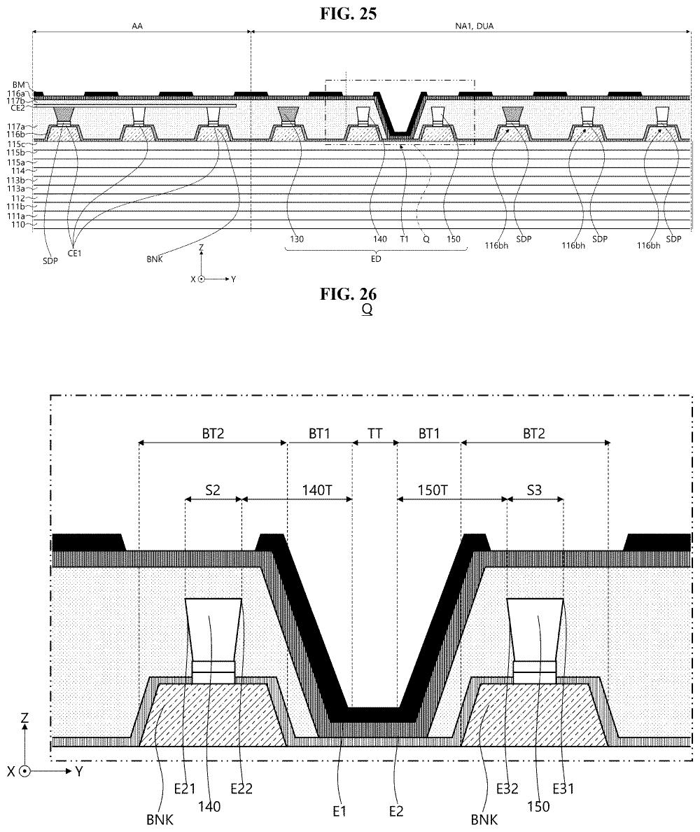

FIG. 25 is a cross-sectional view corresponding to the display device according to the third embodiment. FIG. 26 is a partially enlarged view of portion Q in FIG. 25.

Referring to FIG. 26, the first trench T1 may include a first end E1 and a second end E2 facing each other. The second light-emitting element 140 may include a 2-1 end E21 relatively far from the first end E1 and a 2-2 end E22 relatively close to the first end E1. The third light-emitting element 150 may include a 3-1 end E31 relatively far from the second end E2 and a 3-2 end E32 relatively close to the second end E2.

A distance BT1 between the first end E1 and one end (or one side) of the bank BNK on which the second light-emitting element 140 is disposed and a distance BT1 between the second end E2 and one end (or one side) of the bank BNK on which the third light-emitting element 150 is disposed may be substantially the same. A distance BT2 between one end (or one side) and the other end (or other side) of the bank BNK on which the second light-emitting element 140 is disposed and a distance BT2 between one end (or one side) and the other end (or other side) of the bank BNK on which the third light-emitting element 150 is disposed may be substantially the same. A distance TT between the first end E1 and the second end E2 may be less than the distance BT1 between the first end E1 or the second end E2 and one end (or one side) of the bank BNK on which the light-emitting element is disposed. The distance TT between the first end E1 and the second end E2 may be less than the distance BT2 between one end (or one side) and the other end (or the other side) of the bank BNK on which the light-emitting element is disposed.

The second light-emitting element 140 may have a second size. The second size may be proportional to a distance S2 between the 2-1 end E21 and the 2-2 end E22. The third light-emitting element 150 may have a third size. The third size may be proportional to a distance S3 between the 3-1 end E31 and the 3-2 end E32. The third size and the second size may be substantially the same. As the first trench T1 is disposed between the second light-emitting element 140 and the third light-emitting element 150, a distance 140T between the first end E1 and the 2-2 end E22 may be substantially the same as a distance 150T between the second end E2 and the 3-2 end E32, and be larger than the distance 130T in the above-described embodiment according to FIG. 24. Accordingly, since design margin of the light-emitting element may be secured, the probability of the defective transfer of the light-emitting element in the manufacturing process of the display panel may be reduced. Accordingly, the productivity of the display device may be enhanced.

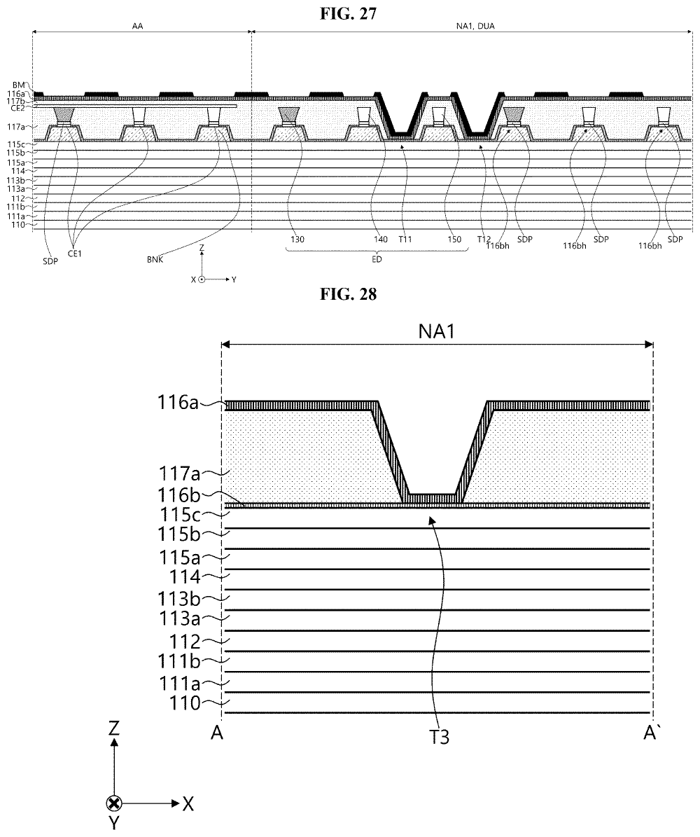

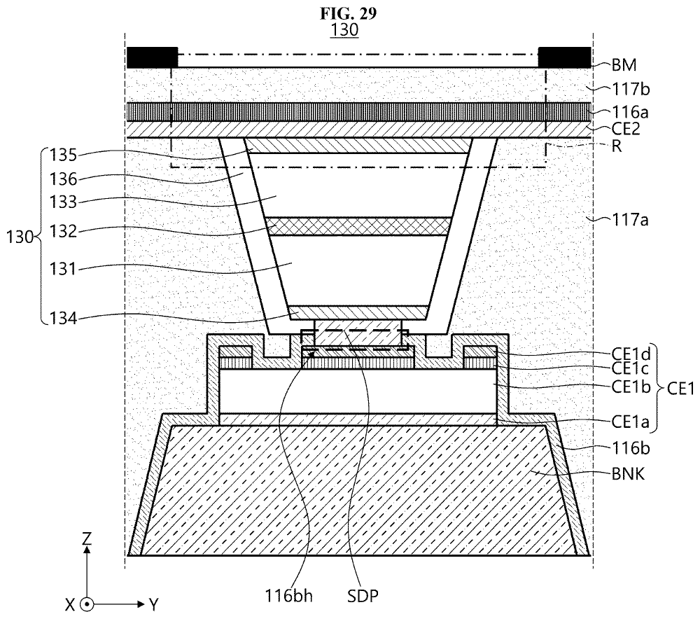

FIG. 27 is a cross-sectional view corresponding to the display device according to the sixth embodiment. FIG. 28 is a cross-sectional view taken along line A-A′ in FIG. 13. Configurations that are substantially the same as the above-described embodiments are denoted by the same reference numerals, and detailed descriptions thereof will be omitted.

Referring to FIG. 27, the display device may include a plurality of trenches T11 and T12. A 1-1 trench T11 may be disposed between the second light-emitting element 140 and the third light-emitting element 150. A 1-2 trench T12 may be disposed between the third light-emitting element 150 and the first light-emitting element 130.

Referring to FIG. 28, the display device may include the first optical layer 117a. As at least a portion of the first optical layer 117a is removed, a third trench T3 may be formed. Referring to a plan view corresponding to the sixth embodiment, the light-emitting element may not be disposed between the bending region and the third trench T3. Further, since a region where the second optical layer extends is substantially the same as a region where the second electrode extends, the display device may not include the second optical layer. Accordingly, a thickness (for example, a length in the Z-axis direction) may be smaller than a region where the second optical layer is formed.

According to the present specification, the first passivation layer 116a may be entirely disposed over the display region AA and the first non-display region NA1. Since the display device according to the embodiment of the present specification is configured to include the first passivation layer 116a and the third trench T3, moisture penetration from the outside of the display device may be prevented, and thus the lifespan of the display device may be enhanced. Accordingly, a display device which has reduced power consumption and may be driven with low power may be provided.

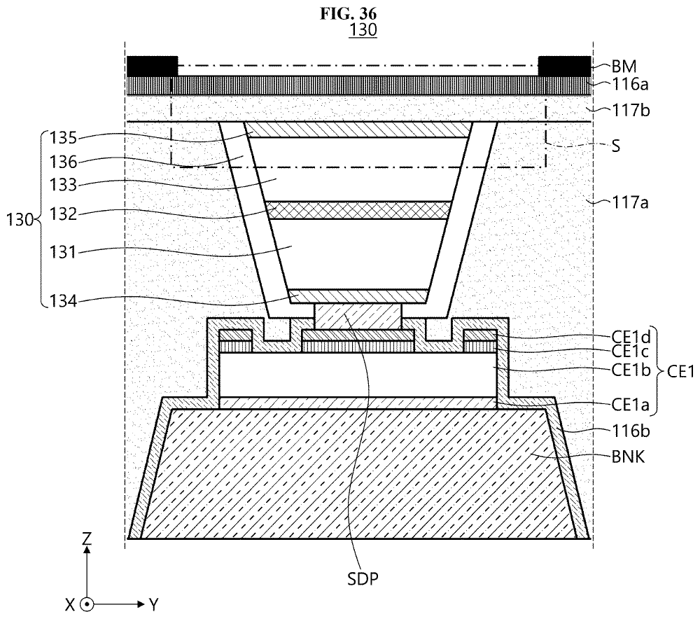

FIG. 29 is a cross-sectional view showing the display device according to the embodiment of the present specification. FIG. 36 is a cross-sectional view showing the display device according to the embodiment of the present specification.

FIG. 29 is a cross-sectional view showing the subpixel including the light-emitting elements disposed in the display region AA.

FIG. 36 is a cross-sectional view showing the subpixel including the light-emitting elements disposed in the dummy region DUA. Configurations that are substantially the same between the cross-sectional views are denoted by the same reference numerals, and detailed descriptions thereof will be omitted.

Referring to FIGS. 29 and 36, the first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be formed of titanium (Ti), molybdenum (Mo), aluminum (Al), or indium tin oxide (ITO), but the embodiments of the present specification are not limited thereto.

According to the present specification, some conductive layers having excellent reflection efficiency among the plurality of conductive layers constituting the first electrode CE1 may be configured as alignment keys for aligning the light-emitting elements ED and/or reflective plates. For example, the second conductive layer CE1b among the plurality of conductive layers of the first electrode CE1 may include a reflective material. For example, the second conductive layer CE1b may include aluminum (Al), but the embodiments of the present specification are not limited thereto. Accordingly, the second conductive layer CE1b may be configured as a reflective plate. Further, identification in the manufacturing process may be facilitated due to the high reflective efficiency of the second conductive layer CE1b, and thus a position or transfer position of the light-emitting element ED may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, portions of the third conductive layer CE1c and fourth conductive layer CE1d disposed on the bank BNK may be removed or etched to expose an upper surface of the second conductive layer CE1b. For example, in the third conductive layer CE1c and the fourth conductive layer CE1d, center portions and edge portions where a solder pattern SDP is disposed may be left, and the remaining portion may be removed. For example, the edge portion of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1. For example, the solder pattern SDP may be a pattern layer or a pattern, but the present specification is not limited to the term.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) having excellent adhesion to the solder pattern SDP and having corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present specification are not limited thereto.

According to the present specification, the signal line TL, the contact electrode CCE, and the pad electrode PE disposed on the same layer as the first electrode CE1 may be formed of multiple layers of a conductive material, but the embodiments of the present specification are not limited thereto. For example, the signal line TL, the contact electrode CCE, and the pad electrode PE may be formed of multiple layers of indium tin oxide (ITO)/titanium (Ti)/aluminum (Al)/titanium (Ti), but the embodiments of the present specification are not limited thereto.

According to the present specification, the solder pattern SDP may be disposed on the first electrode CE1 in each of the plurality of subpixels. The solder pattern SDP may bond the light-emitting element ED to the first electrode CE1. The first electrode CE1 and the light-emitting element ED may be electrically connected by eutectic bonding using the solder pattern SDP, but the embodiments of the present specification are not limited thereto. The first electrode CE1 and the anode electrode 134 of the light-emitting element ED may be electrically connected by eutectic bonding using the solder pattern SDP, but the embodiments of the present specification are not limited thereto. For example, when the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 by eutectic bonding without a separate adhesive. For example, the solder pattern SDP may be formed of indium (In), tin (Sn), or an alloy thereof, but the embodiments of the present specification are not limited thereto. For example, the solder pattern SDP may be a bonding pad or a joining pad, but the embodiments of the present specification are not limited thereto.

According to the present specification, the second passivation layer 116b may be disposed on the plurality of signal lines TL, the plurality of first electrodes CE1, the plurality of contact electrodes CCE, and the third insulating layer 115c. For example, the second passivation layer 116b may be disposed in the display region AA, the first non-display region NA1, and the second non-display region NA2. A portion of the second passivation layer 116b disposed in the bending region BA may be removed. A portion of the second passivation layer 116b covering the plurality of pad electrodes PE in the second non-display region NA2 may be removed. Since the second passivation layer 116b is disposed to cover the remaining region excluding regions where the bending region BA, the plurality of pad electrodes PE, and the solder pattern SDP are disposed, the penetration of moisture or impurities into the light-emitting element ED may be reduced. For example, the second passivation layer 116b may be formed of a single layer or multiple layers of silicon oxide (SiOx) or silicon nitride (SiNx), but the embodiments of the present specification are not limited thereto. For example, the second passivation layer 116b may be a protective layer or an insulating layer, but the embodiments of the present specification are not limited thereto. Further, the second passivation layer 116b may include a hole 116bh which exposes the solder pattern SDP.

The light-emitting element ED may be disposed on the solder pattern SDP in each of the plurality of subpixels. The first light-emitting element 130 may be disposed in the first subpixel SP1. The second light-emitting element 140 may be disposed in the second subpixel SP2. The third light-emitting element 150 may be disposed in the third subpixel SP3.

The light-emitting element ED may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like, but the embodiments of the present specification are not limited thereto.

Referring to FIGS. 29 and 36, the first light-emitting element 130 may include the anode electrode 134, a first semiconductor layer 131, an active layer 132, a second semiconductor layer 133, the cathode electrode 135, and an encapsulation film 136, but the embodiments of the present specification are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented with a group III-V compound semiconductor, a group II-VI compound semiconductor, or the like, and may be doped with impurities (or dopant). For example, one of the first semiconductor layer 131 and the second semiconductor layer 133 may be a semiconductor layer doped with n-type impurities and the other may be a semiconductor layer doped with p-type impurities, but the embodiments of the present specification are not limited thereto. For example, one or more of the first semiconductor layer 131 and the second semiconductor layer 133 may be layers in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like is doped with n-type impurities or p-type impurities, but the embodiments of the present specification are not limited thereto. For example, the n-type impurities may be silicon (Si), germanium (Ge), selenium (Se), carbon (C), tellurium (Te), tin (Sn), or the like, but the embodiments of the present specification are not limited thereto. For example, the p-type impurities may be magnesium (Mg), zinc (Zn), calcium (Ca), strontium (Sr), barium (Ba), beryllium (Be), or the like, but the embodiments of the present specification are not limited thereto.

For example, the first semiconductor layer 131 and the second semiconductor layer 133 may be a nitride semiconductor containing n-type impurities and a nitride semiconductor containing p-type impurities, respectively, but the embodiments of the present specification are not limited thereto. For example, the first semiconductor layer 131 may be a nitride semiconductor containing p-type impurities, and the second semiconductor layer 133 may be a nitride semiconductor containing n-type impurities, but the embodiments of the present specification are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may have any one of a single well structure, a multi-well structure, a single quantum well structure, a multi quantum well (MQW) structure, a quantum dot structure, and a quantum line structure, but the embodiments of the present specification are not limited thereto. For example, the active layer 132 may be formed of indium gallium nitride (InGaN) or gallium nitride (GaN), but the embodiments of the present specification are not limited thereto.

For another example, the active layer 132 may include a multi quantum well (MQW) structure having a well layer and a barrier layer having a higher band gap than the well layer. For example, the active layer 132 may include an InGaN well layer and an AlGaN barrier layer, but the embodiments of the present specification are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material which may be eutectically bonded to the solder pattern SDP, but the embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present specification are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material so that the light emitted from the light-emitting element ED may be directed toward an upper portion of the light-emitting element ED, but the embodiments of the present specification are not limited thereto. For example, the cathode electrode 135 may be formed of a material such as indium tin oxide (ITO), indium zinc oxide (IZO), or indium gallium zinc oxide (IGZO), but the embodiments of the present specification are not limited thereto.

The encapsulation film 136 may be disposed on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least portions of the anode electrode 134 and the cathode electrode 135, for example, an edge portion (or one side) of the anode electrode 134 and an edge portion (or one side) of the cathode electrode 135. Since at least a portion of the anode electrode 134 may be exposed from the encapsulation film 136, the anode electrode 134 and the solder pattern SDP may be connected. For example, since at least a portion of the cathode electrode 135 may be exposed from the encapsulation film 136, the cathode electrode 135 and the second electrode CE2 may be connected. For example, the encapsulation film 136 may be formed of an insulating material such as silicon nitride (SiNx) or silicon oxide (SiOx), but the embodiments of the present specification are not limited thereto.

For another example, the encapsulation film 136 may have a structure in which a reflective material is dispersed in a resin layer, but the embodiments of the present specification are not limited thereto. For example, the encapsulation film 136 may be manufactured as a reflector having various structures, but the embodiments of the present specification are not limited thereto. Since light emitted from the active layer 132 may be reflected upward by the encapsulation film 136, light extraction efficiency may be enhanced. For example, the encapsulation film 136 may be a reflective layer, but the embodiments of the present specification are not limited thereto.

According to the present specification, although the light-emitting element ED is described as having a vertical type structure, the embodiments of the present specification are not limited thereto. For example, the light-emitting element ED may have a lateral structure or a flip chip structure.

Although the first light-emitting element 130 has been described with reference to FIGS. 29 and 36, the second light-emitting element 140 and the third light-emitting element 150 may have substantially the same structure as the first light-emitting element 130. For example, the structures of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130. However, the present specification is not limited thereto.

Referring to FIG. 36, the first electrode CE1 and the plurality of light-emitting elements may be disposed in the dummy region. The second electrode CE2 may not be disposed in the dummy region. Accordingly, the cathode voltage is not supplied to the dummy region through the second electrode CE2, and the light-emitting elements may not emit light.

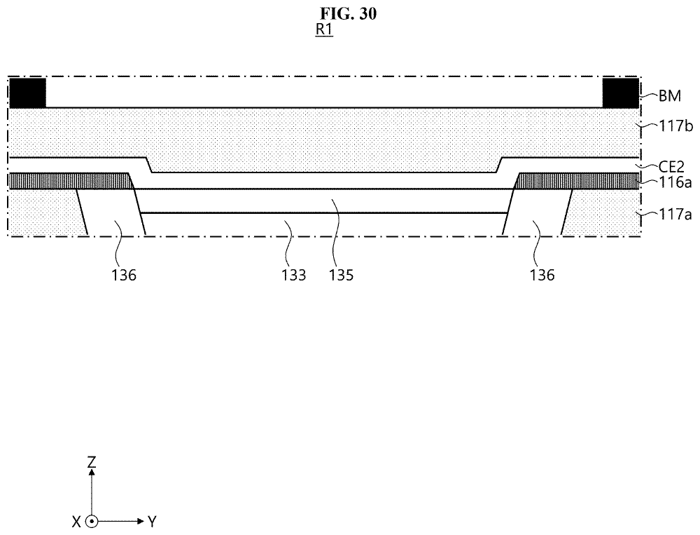

FIGS. 30 to 35 and FIGS. 37 and 38 are cross-sectional views showing display devices according to the embodiments of the present specification.

FIGS. 30 to 35 are partially enlarged views R1, R2, R3, R4, and R6 of portion R in FIG. 29, respectively. FIGS. 30 to 35 respectively show display devices according to a twelfth embodiment to a seventeenth embodiment. Configurations that are substantially the same as those in the above-described embodiment are denoted by the same reference numerals, and detailed descriptions thereof will be omitted.

Referring to FIG. 30, a display device R1 according to the twelfth embodiment may include a first passivation layer 116a disposed on a first optical layer 117a. A second electrode CE2 may be disposed on the first optical layer 117a. In order to emit light, the second electrode CE2 may have a structure for coming into contact with light-emitting elements. For example, the second electrode CE2 may have a structure which covers the first passivation layer 116a so that at least a portion of the first passivation layer 116a may be removed and the light-emitting elements may be in contact with the second electrode CE2. A second optical layer 117b may be disposed on the second electrode CE2. A black matrix BM may be disposed on the second optical layer 117b.

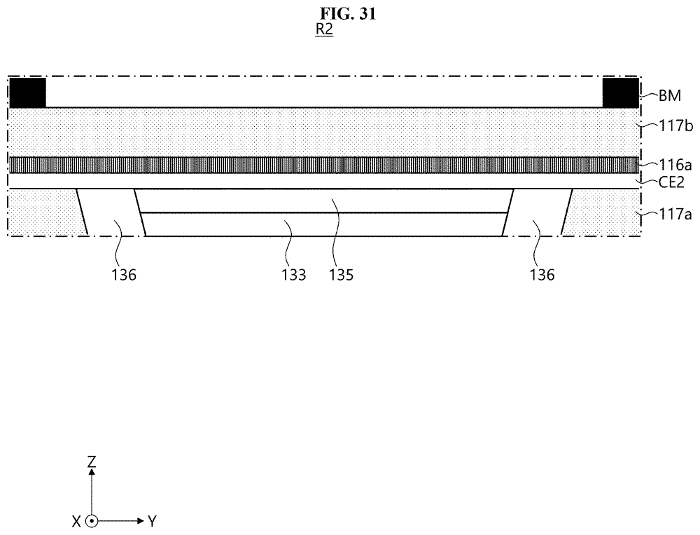

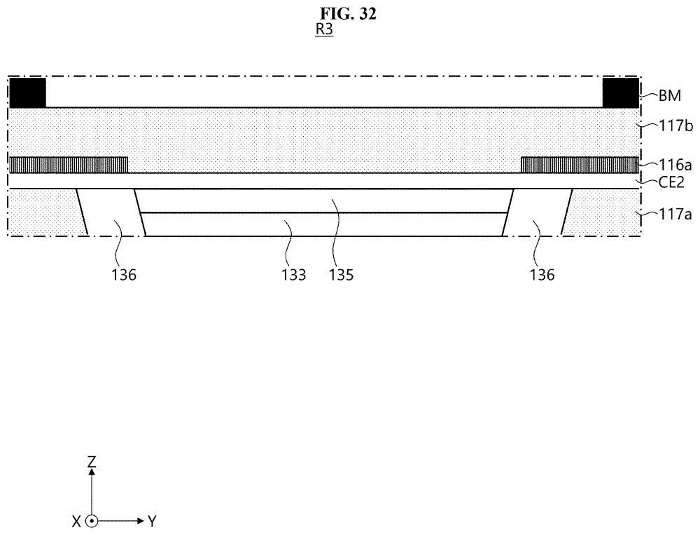

Referring to FIG. 31, a display device R2 according to the thirteenth embodiment may include a second electrode CE2 disposed on a first optical layer 117a. The second electrode CE2 may be in contact with light-emitting elements. A first passivation layer 116a may be disposed on the second electrode CE2. A second optical layer 117b may be disposed on the first passivation layer 116a. A black matrix BM may be disposed on the second optical layer 117b.

Referring to FIG. 32, in a display device R3 according to the fourteenth embodiment, at least a portion of a first passivation layer 116a disposed on a second electrode CE2 may be removed. A second optical layer 117b may be disposed on the first passivation layer 116a. A black matrix BM may be disposed on the second optical layer 117b. When the first passivation layer 116a is formed of an opaque material, light from the light-emitting elements may pass through the second optical layer 117b without passing through the first passivation layer 116a due to the configuration. Accordingly, the light efficiency of the light-emitting elements may be improved.

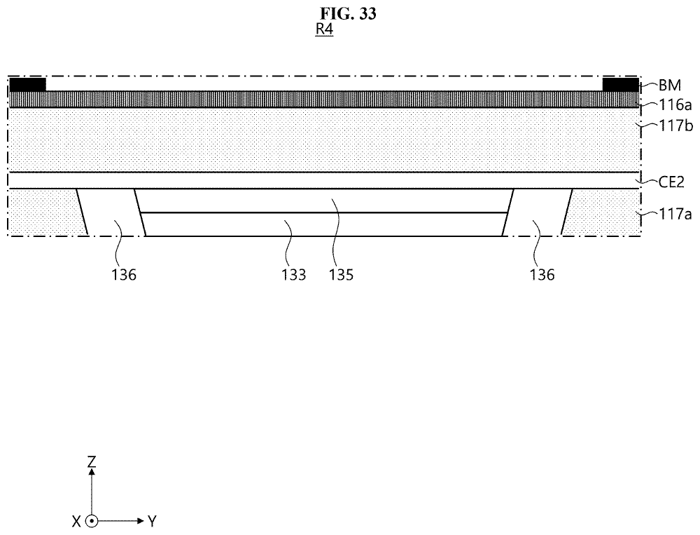

Referring to FIG. 33, a display device R4 according to the fifteenth embodiment may include a first passivation layer 116a disposed on a second optical layer 117b. The second optical layer 117b may be disposed on the first passivation layer 116a. A black matrix BM may be disposed on the second optical layer 117b. Accordingly, the first passivation layer 116a may protect both the first optical layer 117a and the second optical layer 117b, and the reliability of the display device may be enhanced and color reproducibility may be enhanced. The black matrix BM may be disposed on the first passivation layer 116a.

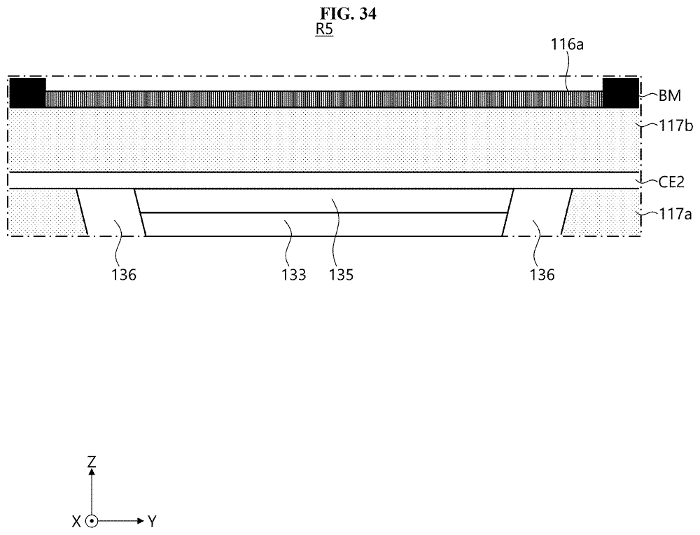

Referring to FIG. 34, in a display device R5 according to the sixteenth embodiment, a second electrode CE2 may be disposed on a first optical layer 117a. A second optical layer 117b may be disposed on the second electrode CE2. A first passivation layer 116a and a black matrix BM may be disposed on the second optical layer 117b. The black matrix BM may be disposed around or at an edge of the first passivation layer 116a. When the first passivation layer 116a is formed of a transparent material, visibility by the black matrix BM may be improved due to the configuration.

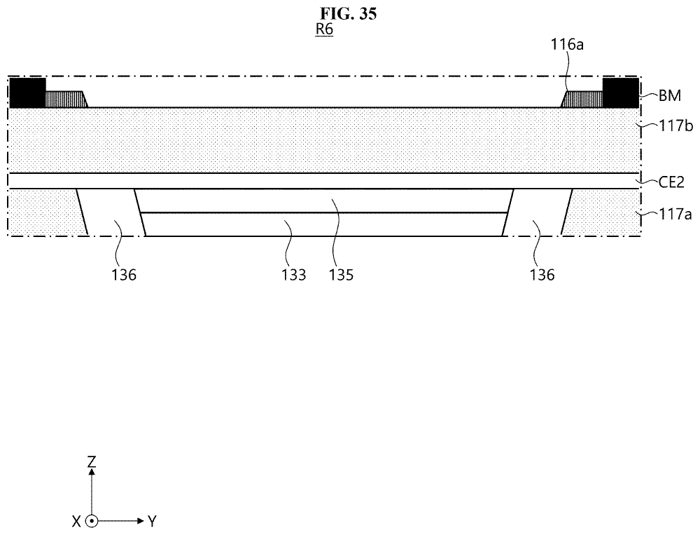

Referring to FIG. 35, in a display device R6 according to the seventeenth embodiment, a second electrode CE2 may be disposed on a first optical layer 117a. A second optical layer 117b may be disposed on the second electrode CE2. At least a portion of a first passivation layer 116a disposed on the second optical layer 117b may be removed. A black matrix BM may be disposed around or at an edge of the first passivation layer 116a. When the first passivation layer 116a is formed of an opaque material, light from the light-emitting elements may not pass through the first passivation layer 116a due to the configuration. Accordingly, the light-emitting efficiency of the display device may increase.

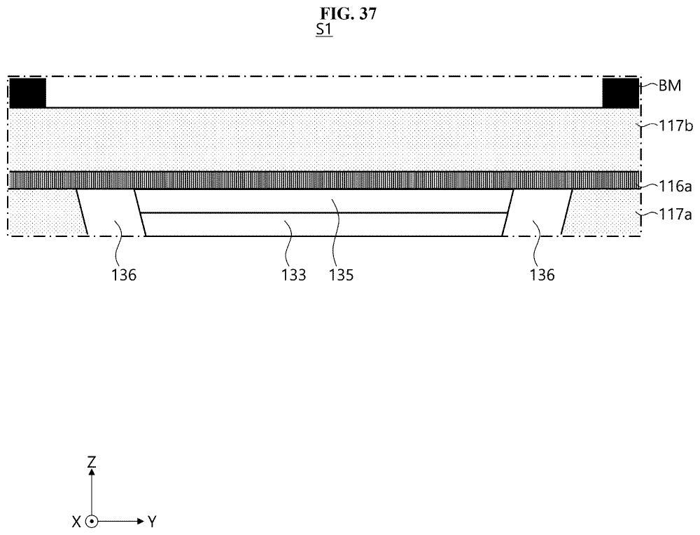

FIGS. 37 to 39 are partially enlarged views S1, S2, and S3 of portion S in FIG. 36, respectively. FIGS. 37 to 39 respectively show display devices according to an eighteenth embodiment to a twentieth embodiment.

Referring to FIG. 37, in a display device S1 according to the eighteenth embodiment, a first passivation layer 116a may be disposed between a first optical layer 117a and a second optical layer 117b. A black matrix BM may be disposed on the second optical layer 117b. The black matrix BM may be disposed on the first passivation layer 116a. The black matrix BM may be disposed around or at an edge of the first passivation layer 116a.

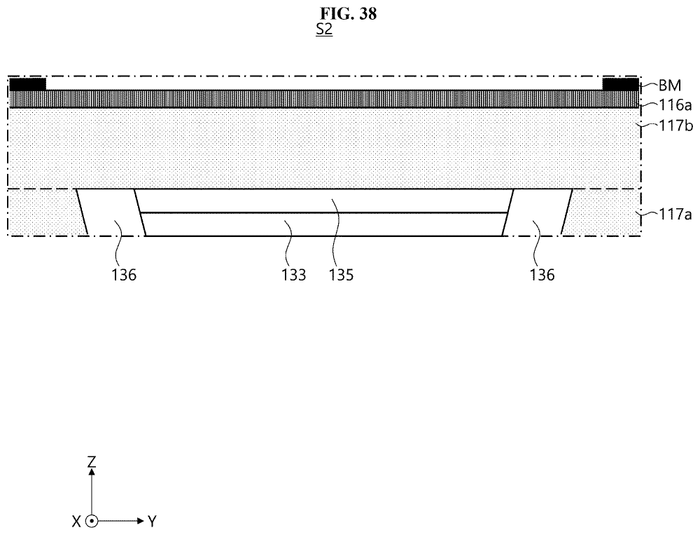

Referring to FIG. 38, in a display device S2 according to the nineteenth embodiment, a first passivation layer 116a may be disposed on a second optical layer 117b. The first passivation layer 116a may be disposed between the second optical layer 117b and a black matrix BM. The black matrix BM may be disposed around or at an edge of the first passivation layer 116a.

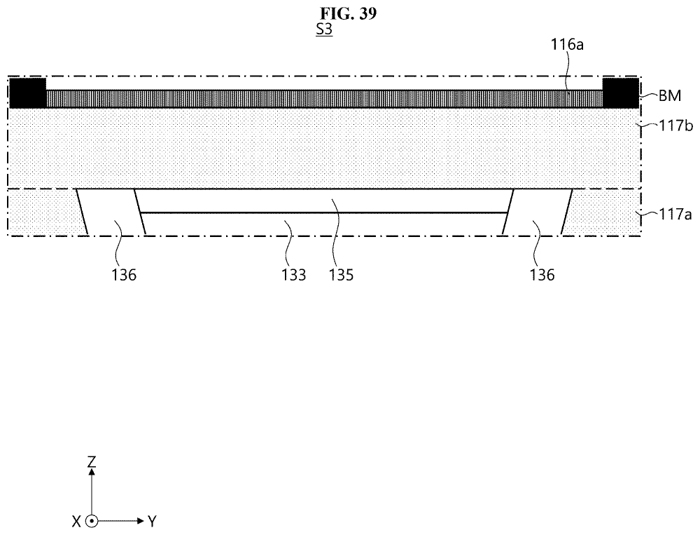

Referring to FIG. 39, in a display device S3 according to the twentieth embodiment, a first passivation layer 116a may be disposed on a second optical layer 117b. The first passivation layer 116a may be disposed between a plurality of black matrices BM. The black matrix BM may be disposed around or at an edge of the first passivation layer 116a.

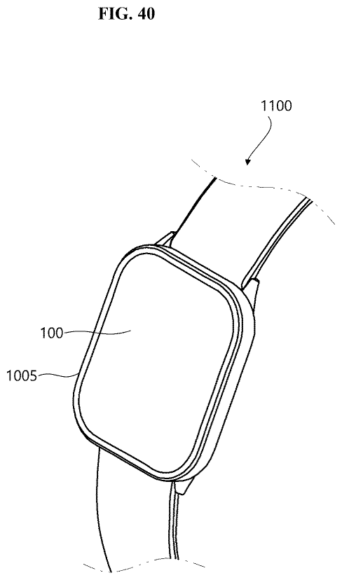

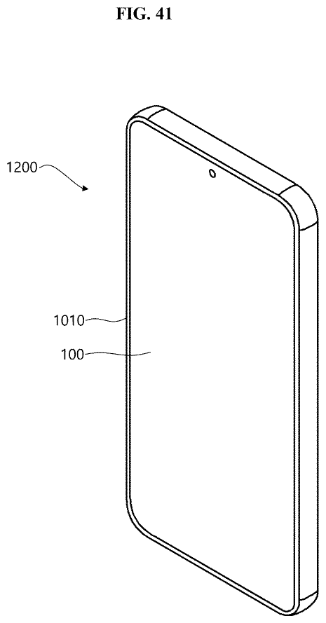

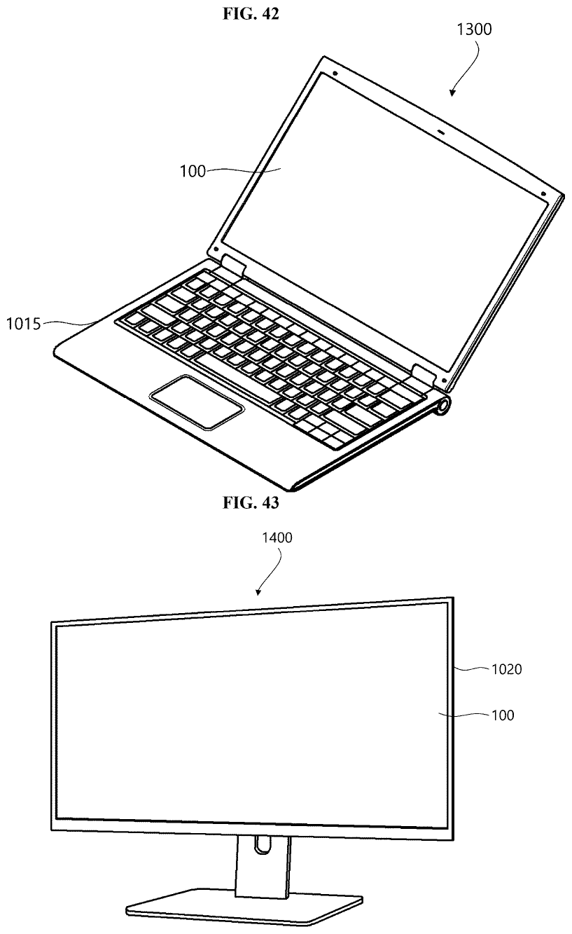

FIGS. 40 to 43 are views showing devices to which the display devices according to the embodiments of the present specification are applied.

Referring to FIGS. 40 to 43, the display devices 1000 according to the embodiments of the present specification may be included in various devices or electronic devices. For example, referring to FIGS. 40 to 43, various electronic devices may include a wearable device 1100, a mobile device 1200, a notebook 1300, and a monitor or television (TV) 1400, but the embodiments of the present specification are not limited thereto.

The wearable device 1100, the mobile device 1200, the notebook 1300, and the monitor or TV 1400 may respectively include case portions 1005, 1010, 1015, and 1020, and the above-described display panels 100 and display devices 1000 according to the embodiments of the present specification.

For example, the display devices according to the embodiments of the present specification may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a gaming apparatus, a notebook, a monitor, a camera, a camcorder, a home appliance, and the like.

The display devices according to various embodiments of the present specification may be described as follows.

In one embodiment, a display device comprises: a substrate; a plurality of inorganic light-emitting elements on the substrate; a first optical layer around the plurality of inorganic light-emitting elements; a second optical layer on the plurality of inorganic light-emitting elements and the first optical layer; and a first passivation layer on the first optical layer such that the first passivation layer is farther from the substrate than the first optical layer.

In one embodiment, the substrate includes a display region and a non-display region around the display region, and the display device further comprises a second electrode in the display region but not the non-display region, the second electrode being on the plurality of inorganic light-emitting elements in the display region, and a trench in the non-display region, the trench surrounding the display region.

In one embodiment, the first optical layer and the second optical layer are in the display region and the non-display region.

In one embodiment, the non-display region includes a dummy region including dummy pixels, and the second optical layer is on the dummy pixels in the dummy region.

In one embodiment, the non-display region includes a plurality of dummy light-emitting elements in the dummy pixels that do not emit light, and the trench is between the plurality of dummy light-emitting elements in the dummy region.

In one embodiment, the trench extends through each of the first optical layer and the second optical layer in the dummy region.

In one embodiment, the first passivation layer is disposed in the trench in the dummy region.

In one embodiment, each of the plurality of inorganic light-emitting elements includes an anode electrode, a first semiconductor layer on the anode electrode, an active layer on the first semiconductor layer, a second semiconductor layer on the active layer, and a cathode electrode on the second semiconductor layer.

In one embodiment, each of the plurality of inorganic light-emitting elements has a vertical type structure.

In one embodiment, the display device further comprises a first electrode under an inorganic light-emitting element from the plurality of inorganic light-emitting elements, the first electrode electrically connected to the anode electrode of the inorganic light-emitting element, and a pattern layer between the first electrode and the anode electrode, the pattern layer electrically connecting the first electrode and the anode electrode of the inorganic light-emitting element.

In one embodiment, the substrate includes a display region and a non-display region around the display region, and the display device further comprises a plurality of inorganic light-emitting elements in the display region, one or more pixel driving circuits on the substrate, the one or more pixel driving circuits connected to the plurality of inorganic light-emitting elements, and a plurality of connection lines on the one or more pixel driving circuits, the plurality of connection lines connected to the one or more pixel driving circuits, wherein the plurality of connection lines are spaced apart from each other and disposed on a same layer.

In one embodiment, the substrate includes a display region and a non-display region disposed around the display region, the display device further comprises a plurality of inorganic light-emitting elements in the display region, one or more pixel driving circuits on the substrate, the one or more pixel driving circuits connected to the plurality of inorganic light-emitting elements, a plurality of connection lines on the one or more pixel driving circuits, the plurality of connection lines connected to the one or more pixel driving circuits, and a plurality of insulating layers between the plurality of connection lines, wherein the plurality of connection lines are on different layers and offset from each other with the plurality of insulating layers therebetween.

In one embodiment, the display device further comprises a bending region extending from the non-display region, wherein insulating layers from the plurality of insulating layers that are adjacent to a plurality of banks in the plurality of inorganic light-emitting elements are not in the bending region.

In one embodiment, a thickness of an insulating layer from the plurality of insulating layers that is adjacent to each of the plurality of banks in each of the plurality of inorganic light-emitting elements and a thickness of an insulating layer from the plurality of insulating layers that is on the one or more pixel driving circuits is greater than a thickness of an insulating layer from the plurality of insulating layers that is between the plurality of banks and the one or more pixel driving circuits.

In one embodiment, the display device further comprises a plurality of pad electrodes connected to the one or more pixel driving circuits, and other connection lines connected to the plurality of pad electrodes and the one or more pixel driving circuits.

In one embodiment, the other connection lines are on a same layer as connection lines from the plurality of connection lines that are on the one or more pixel driving circuits.

In one embodiment, the display device further comprises a second electrode on the plurality of inorganic light-emitting elements.

In one embodiment, the first passivation layer is between the first optical layer and the second optical layer.

In one embodiment, the first passivation layer is between the second electrode and the second optical layer.

In one embodiment, the first passivation layer is on the second optical layer.

In one embodiment, the display device further comprises a black matrix on the second optical layer, wherein the first passivation layer is between the second optical layer and the black matrix.

In one embodiment, the display device further comprises a pixel driving circuit connected to the plurality of inorganic light-emitting elements, the pixel driving circuit including a plurality of pixel circuits, and a second passivation layer between the pixel driving circuit and the plurality of inorganic light-emitting elements.

In one embodiment, a thickness of the first passivation layer is different from a thickness of the second passivation layer.

In one embodiment, the display device further comprises a plurality of banks between the pixel driving circuit and the second passivation layer.

In one embodiment, the display device further comprises a pattern layer between the plurality of banks and the plurality of inorganic light-emitting elements, wherein a hole in the second passivation layer exposes a portion of the pattern layer.

In one embodiment, the display device further comprises a plurality of first electrodes between the plurality of banks and the pattern layer.

In one embodiment, a display device comprises: a display panel including a plurality of pixels, each of the plurality of pixels including a plurality of light-emitting elements; an optical layer in the plurality of pixels; and a trench in the plurality of pixels, wherein the trench includes a first trench between a first pair of light-emitting elements from the plurality of light-emitting elements and a second trench between a second pair of light-emitting elements from the plurality of light-emitting elements, and wherein the optical layer includes a first optical layer around the plurality of light-emitting elements and a second optical layer on the plurality of light-emitting elements and the first optical layer.

In one embodiment, the first trench extends in a first direction and the second trench extends in a second direction intersecting the first direction.

In one embodiment, the display device further comprises a bending region in a first direction from the display panel, wherein the trench further includes a third trench between the display panel and the bending region, the third trench extending in a second direction intersecting the first direction.

In one embodiment, the display device further comprises a first passivation layer on the first optical layer.

region and a non-display region that surrounds the display region; a first inorganic light-emitting element in the display region; a second inorganic light-emitting element in the non-display region; a first optical layer around the first inorganic light-emitting element in the display region and around the second inorganic light-emitting element in the non-display region; a second optical layer on the first inorganic light-emitting element and a first portion of the first optical layer in the display region and on the second inorganic light-emitting element and a second portion of the first optical layer in the non-display region; and a trench through the first optical layer and the second optical layer in the non-display region, wherein the trench is disposed between the first inorganic light-emitting element and the second inorganic light-emitting element.

In one embodiment, the display device further comprises a passivation layer on the first optical layer such that the passivation layer is farther from the substrate than the first optical layer.

In one embodiment, a portion of the passivation layer is disposed in the trench.

In one embodiment, the second optical layer is between the passivation layer and the first optical layer in the display region and the non-display region.

In one embodiment, the passivation layer is between the second optical layer and the first optical layer in the display region and the non-display region.

According to the present specification, since a display device can be protected from moisture penetration from the outside, the reliability of the display device can be enhanced.

Since moisture penetration from the outside of the display device can be prevented, the lifespan of the display device can be enhanced. Accordingly, a display device which has reduced power consumption and can be driven with low power can be provided.

The probability of the defective transfer of light-emitting elements in a manufacturing process of a display panel can be reduced. Accordingly, the productivity of the display device can be enhanced.

The effects according to the present specification are not limited to the above-mentioned effects, and other effects which are not mentioned can be clearly understood by those skilled in the art from the disclosure to be described below.

Although the embodiments of the present disclosure have been described in more detail with reference to the accompanying drawings, the present disclosure is not necessarily limited to these embodiments, and may be variously modified without departing from the technical spirit of the present disclosure.

Accordingly, the embodiments disclosed in the present specification are not intended to limit the technical spirit of the present specification but illustrate it, and the scope of the technical spirit of the present specification is not limited by these embodiments.

Accordingly, the above-described embodiments should be understood as exemplary in all aspects and not restrictive.

The scope of the present disclosure should be interpreted by the claims, and it should be interpreted that all technical ideas within the equivalent range are included in the scope of the present disclosure.

What is claimed is:

1. A display device comprising:
a substrate;
a plurality of inorganic light-emitting elements on the substrate;
a first optical layer around the plurality of inorganic light-emitting elements;
a second optical layer on the plurality of inorganic light-emitting elements and the first optical layer; and
a first passivation layer on the first optical layer such that the first passivation layer is farther from the substrate than the first optical layer.

2. The display device of claim 1, wherein the substrate includes a display region and a non-display region around the display region, and the display device further comprises:
a second electrode in the display region, the second electrode on the plurality of inorganic light-emitting elements in the display region; and
a trench in the non-display region, the trench surrounding the display region.

3. The display device of claim 2, wherein the first optical layer and the second optical layer are in the display region and the non-display region.

4. The display device of claim 3, wherein the non-display region includes a dummy region including dummy pixels and the second optical layer is on the dummy pixels in the dummy region.

5. The display device of claim 4, wherein the non-display region includes a plurality of dummy light-emitting elements in the dummy pixels that do not emit light and the trench is between the plurality of dummy light-emitting elements in the dummy region.

6. The display device of claim 5, wherein the trench extends through each of the first optical layer and the second optical layer in the dummy region.

7. The display device of claim 6, wherein the first passivation layer is disposed in the trench in the dummy region.

8. The display device of claim 1, wherein the substrate includes a display region and a non-display region around the display region,
the display device further comprising:
a plurality of inorganic light-emitting elements in the display region;
one or more pixel driving circuits on the substrate, the one or more pixel driving circuits connected to the plurality of inorganic light-emitting elements; and
a plurality of connection lines on the one or more pixel driving circuits, the plurality of connection lines connected to the one or more pixel driving circuits,
wherein the plurality of connection lines are spaced apart from each other and disposed on a same layer.

9. The display device of claim 1, wherein the substrate includes a display region and a non-display region disposed around the display region, the display device further comprising:
a plurality of inorganic light-emitting elements in the display region;
one or more pixel driving circuits on the substrate, the one or more pixel driving circuits connected to the plurality of inorganic light-emitting elements;
a plurality of connection lines on the one or more pixel driving circuits, the plurality of connection lines connected to the one or more pixel driving circuits; and
a plurality of insulating layers between the plurality of connection lines,
wherein the plurality of connection lines are on different layers and offset from each other with the plurality of insulating layers therebetween.

10. The display device of claim 9, further comprising:
a bending region extending from the non-display region,
wherein insulating layers from the plurality of insulating layers that are adjacent to a plurality of banks in the plurality of inorganic light-emitting elements are not in the bending region,
wherein a thickness of an insulating layer from the plurality of insulating layers that is adjacent to each of the plurality of banks in each of the plurality of inorganic light-emitting elements and a thickness of an insulating layer from the plurality of insulating layers that is on the one or more pixel driving circuits is greater than a thickness of an insulating layer from the plurality of insulating layers that is between the plurality of banks and the one or more pixel driving circuits.

11. The display device of claim 8, further comprising:
a plurality of pad electrodes connected to the one or more pixel driving circuits; and
other connection lines connected to the plurality of pad electrodes and the one or more pixel driving circuits,
wherein the other connection lines are on a same layer as connection lines from the plurality of connection lines that are on the one or more pixel driving circuits.

12. The display device of claim 1, wherein the first passivation layer is between the first optical layer and the second optical layer.

13. The display device of claim 1, further comprising:
a second electrode on the plurality of inorganic light-emitting elements,
wherein the first passivation layer is between the second electrode and the second optical layer.

14. The display device of claim 1, wherein the first passivation layer is on the second optical layer,
wherein the first passivation layer is between the second optical layer and the black matrix.

15. The display device of claim 1, further comprising:
a pixel driving circuit connected to the plurality of inorganic light-emitting elements, the pixel driving circuit including a plurality of pixel circuits; and
a second passivation layer between the pixel driving circuit and the plurality of inorganic light-emitting elements,
wherein a thickness of the first passivation layer is different from a thickness of the second passivation layer.

16. The display device of claim 1, further comprising:
a pixel driving circuit connected to the plurality of inorganic light-emitting elements, the pixel driving circuit including a plurality of pixel circuits;
a second passivation layer between the pixel driving circuit and the plurality of inorganic light-emitting elements;
a plurality of banks between the pixel driving circuit and the second passivation layer; and
a pattern layer between the plurality of banks and the plurality of inorganic light-emitting elements,
wherein a hole in the second passivation layer exposes a portion of the pattern layer.

17. A display device comprising:
a display panel including a plurality of pixels, each of the plurality of pixels including a plurality of light-emitting elements;
an optical layer in the plurality of pixels; and
a trench in the plurality of pixels,
wherein the trench includes a first trench between a first pair of light-emitting elements from the plurality of light-emitting elements and a second trench between a second pair of light-emitting elements from the plurality of light-emitting elements, and
wherein the optical layer includes a first optical layer around the plurality of light-emitting elements and a second optical layer on the plurality of light-emitting elements and the first optical layer.

18. The display device of claim 17, wherein the first trench extends in a first direction and the second trench extends in a second direction intersecting the first direction.

19. The display device of claim 17, further comprising:
a bending region in a first direction from the display panel,
wherein the trench further includes a third trench between the display panel and the bending region, the third trench extending in a second direction intersecting the first direction.

20. A display device comprising:
a substrate including a display region and a non-display region that surrounds the display region;
a first inorganic light-emitting element in the display region;
a second inorganic light-emitting element in the non-display region;
a first optical layer around the first inorganic light-emitting element in the display region and around the second inorganic light-emitting element in the non-display region;
a second optical layer on the first inorganic light-emitting element and a first portion of the first optical layer in the display region and on the second inorganic light-emitting element and a second portion of the first optical layer in the non-display region; and
a trench through the first optical layer and the second optical layer in the non-display region,
wherein the trench is disposed between the first inorganic light-emitting element and the second inorganic light-emitting element.
